(19) United States
(12) Patent Application Publication
(10) Pub. No.: US 2012/0170102 A1
(43) Pub. Date: Jul. 5, 2012

(54) Spatial Light Modulators and Fabrication Techniques

(76) Inventors: Justin Payne, San Jose, CA (US); Howard Woo, San Jose, CA (US); Vlad Novotny, Los Gatos, CA (US); Adrian James Cable, Harlton (GB)

(21) Appl. No.: 12/983,195

(22) Filed: Dec. 31, 2010

(51) Int. Cl. G02B 26/06; H01L 31/18

(52) U.S. Cl. 359/291; 438/65; 257/E31.127

(57) ABSTRACT

We describe a phase modulating spatial light modulator (SLM). The SLM comprises a substrate bearing multiple SLM pixels, each of the SLM pixels comprising a MEMS (micro electromechanical system) optical phase modulating structure. The MEMS optical phase modulating structure comprises: a pixel electrode; a spring support structure around a perimeter of the pixel electrode; and a mirror spring supported by the spring support structure. The mirror spring comprises a mirror support and a plurality of mirror spring arms each extending between the mirror support and the spring support structure, and a mirror mounted on the mirror support. Each mirror spring arm has a spiral or serpentine shape. A voltage applied to the pixel electrode flexes the mirror spring and causes the mirror to translate perpendicularly to the substrate substantially without tilting.

### COPYRIGHT NOTICE

Contained herein is material that is subject to copyright protection. The copyright owner has no objection to the facsimile reproduction of the patent disclosure by any person as it appears in the Patent and Trademark Office patent files or records, but otherwise reserves all rights to the copyright whatsoever. Copyright © 2010, Light Blue Optics Inc.

### BACKGROUND

1. Field

Embodiments of the present invention generally relate to spatial light modulators, in particular for phase modulation of light for diffractive/holographic imaging systems, and to related fabrication methods.

2. Description of the Related Art

We have previously described various holographic image projection systems (see, for example, WO2007/141567), and more recently a holographic projector in which, broadly speaking, a holographically generated image is used for illumination of a second spatial light modulator (see, for example, WO2010/007404 and U.S. Ser. No. 12/182,095, hereby incorporated by reference in their entirety for all purposes). In this latter approach relatively low resolution phase modulation is employed to render lower spatial frequencies of an image holographically, the higher frequency components being rendered with an intensity modulating imaging panel placed in a plane conjugate to the hologram SLM. In such a system the hologram is preferably a fast, multiphase or quasi analogue-phase device, more particularly a pixellated MEMS (micro electromechanical system)-based piston actuated device.

There are special requirements for an SLM for such a system which are not met by existing SLM devices. In broad terms these are as follows:

The pixels should be small because this increases diffraction angles from the SLM—for example preferably a pixel should be less than 30 μm by 20 μm. It is also important to achieve a high fill factor since unlike a conventional imaging system in a diffractive system efficiency falls very rapidly as the inter-pixel gap increases, very roughly proportional to the linear pixel gap raised to the fourth power. Accurate and repeatable control of the pixels is also important, and this imposes tight constraints on motion control—for example for five bit resolution at approximately 400 nm the phase steps are approximately 13 nm apart. High reflectivity, for example greater than 95%, low operating voltage, and small physical size are also highly desirable.

There are many different designs for MEMS mirror technologies and, broadly speaking, these fall into two groups, those with tilting mirrors and those with piston-type mirror actuation. Examples of tilting mirror technology can be found in patents held by Miradia Inc., for example US2101/112492, US2004/0145822 and US2007/128771. However in this specification we are concerned with piston-type SLM mirror arrays. Examples of piston-type arrays for adapted optics have been developed by Iris AO (Berkeley, Calif.) and Boston Micro Machines Corp.—see, for example, U.S. Pat. No. 7,741,685, U.S. Pat. No. 138,745 and U.S. Pat. No. 7,129,455 (as well as www.bostonmicromachines.com). However these are different classes of device to those required for the aforementioned diffractive/holographic applications, having large pixels (several hundred μm) with large displacements (greater than one μm), and operating at high voltages. These devices are not suitable for scaling down to meet the needs of a diffractive/holographic imaging system.

Another approach, developed by Alcatel for high speed maskless lithography, uses pixel mirrors suspended by long springs which extend under multiple pixels (see D. Lopez, et al., “Two-dimensional MEMS array for maskless lithography and wavefront modulation”, Proceedings of the SPIE Smart Sensors, Actuators, and MEMS III, vol. 6589, 2007). A further approach is that of Fraunhofer IPMS (Institut Photonische Mikrosystems), who have developed a square pixels device (see, for example, A. Gehner, M. Wildenhain, and H. Lakner, “Micromirror arrays for wavefront correction”, Proceedings of SPIE Conference on MOEMS and Miniaturized Systems, vol. 4178, 348, 2000; A. Gehner, W. Doleschal, A. Elgner, R. Kauert, D. Kunze, M. Wildenhain, “Active-matrix addressed micromirror array for wavefront correction in adaptive optics”, Proceedings of SPIE Conference on MOEMS and Miniaturized Systems II, vol. 4561, 265, 2001; J. Schmidt, J. Knobbe, A. Gehner, and H. Lakner, “CMOS integrable micro mirrors with highly improved driftstability”, Proceedings of the SPIE MEMS Adaptive Optics, vol. 6467, 6467R, 2007). However the Fraunhofer devices have a low fill factor, a poor quality reflecting surface, and cannot easily be scaled down to the desired pixel size mentioned above.

Further background prior art can be found in US2008/0220552; US2010/0181631; US2007/0097485; US2006/0082862; U.S. Pat. No. 7,298,539; U.S. Pat. No. 7,245,416; U.S. Pat. No. 7,141,870; U.S. Pat. No. 7,022,245; U.S. Pat. No. 7,068,417; U.S. Pat. No. 6,992,810; and U.S. Pat. No. 7,042,619.

There is therefore a need for improved MEMS spatial light modulator designs, in particular for use in diffractive/holographic imaging applications.

### SUMMARY

According to a first aspect of the present invention there is therefore provided a phase modulating spatial light modulator (SLM), the spatial light modulator comprising: a substrate bearing a plurality of SLM pixels, each of said SLM pixels comprising a EMS micro electromechnical system) optical phase modulating structure; wherein said EMS optical phase modulating structure comprises: a pixel electrode; a spring support structure around a perimeter of said pixel electrode; a mirror spring supported by said spring support structure, wherein said mirror spring comprises a mirror support and a plurality of mirror spring arms each extending between said mirror support and said spring support structure; and a mirror mounted on said mirror support; and wherein a voltage applied to said pixel electrode flexes said mirror spring and causes said mirror to translate perpendicularly to said substrate substantially without tilting.

Embodiments of such a device provide compatibility with monolithic CMOS driving circuitry, a simple fabrication process with a high yield and high reliability at low cost, a low driving voltage and low power dissipation, and a high fill ratio and high optical reflectivity. In some preferred embodiments each mirror spring arm has a spiral or serpentine shape. Preferably the mirror spring is electrically conductive and acts as the second electrode to the pixel electrode on the substrate. Preferably the mirror is mounted on the mirror support part of the mirror spring attached, for example, by a post or ‘stitch’ fabricated in a similar manner to a via. This enables the mirror surface to be separately arranged to provide high reflectivity, for example by providing the mirror with a multi-layer reflective coating.

Where the mirror spring is electrically conductive, preferably a ratio of a distance between the mirror spring arms to a distance between the mirror spring and the pixel electrode is at least 1:2. In some preferred embodiments the mirror spring is substantially planar. Surprisingly, although the mirror spring effectively comprises a perforated structure rather than a continuous plate, provided the pixel electrode is sufficiently far from the mirror spring, because of fringing fields the spring behaves like a substantially continuous electrode surface. In embodiments the in-plane linear distance between spring arms is less than ⅓ or ⅕ of the distance between the mirror spring and the pixel electrode. For example a spring arm width may be around 200 mm, a spring arm spacing around 200 mm, and a distance to the pixel electrode greater than 1000 nm, for example around 1500 nm. In this way the affected area of the mirror spring is greater than the physical area, because of the effects of the fringing electric fields around the spring arm edges.

In some preferred embodiments each mirror spring arm has a generally spiral shape; in embodiments the mirror support has the shape of an (irregular) hexagon around which the arms spiral. A spiral (hexagonal) spring is better than a rectangular spring because for a given fill area greater compliance can be achieved. One may think of such a spiral spring as having more corners, and therefore bending more for the same applied voltage. In some preferred embodiments each spring arm has a length of least 0.5 turns preferably at least 0.8 or 1.0, the number of turns may be between 0.75 and 2. In preferred embodiments, even where the shape of a pixel or mirror support is hexagonal a preferred number of spring arms is 2 or 4. In some preferred embodiments the spring support structure comprises one or more side walls around the perimeter of the pixel electrode and the inner spring is substantially planar and supported by this structure. Preferably each of the mirror spring arms is anchored to the mirror support structure at intervals around the perimeter of the pixel electrode, in embodiments spiraling inwards from there towards the mirror support. Alternatively, however, a folded or serpentine spring arm arrangement may be employed leading from an anchor at the periphery of the pixel towards the central mirror support.

In some preferred embodiments the mirror support and mirror are integrally formed from a single layer of material, preferably comprising (polycrystalline) SiGe. This has good mechanical spring properties and a further advantage which is compatible with CMOS temperature limitations.

Optionally the width of a mirror spring arm may vary over the length of the spring arm, to change the compliance of a spring arm in a radial direction from a peripheral spring support structure towards the centre of the pixel. Thus, for example, a spring arm width may reduce in a direction from the spring support structure towards the mirror support, or vice-versa, in either case providing or compensating for a non-linear response of the spring, more particularly the translational movement of the mirror support, with applied voltage on the pixel electrode.

In preferred embodiments the MEMS phase modulating structure is integrated with a CMOS backplane. Embodiments of the above described structure enable this to be achieved despite CMOS being limited to relatively low subsequent processing temperatures (typically not greater than 425° C.). In some preferred embodiments an optical phase modulating piston-type mirror is mounted over CMOS pixel drive circuitry for the structure. This facilitates accurate low voltage operation in particular with a variable, analogue drive. Alternatively, however, the CMOS driver circuitry may be located to one side of the MEMS pixels, although this is generally less preferable because a relatively large number of relatively long wires is needed to connect the CMOS circuitry to the pixel electrodes, which can result in a loss of speed/efficiency.

In some preferred embodiments a pixel electrode drive voltage may be less than 20 volts, for example in the range 0-12 volts. In preferred embodiments the CMOS process is a multiple metal layer CMOS process.

Separating the mirror and the spring facilitates separate optimisation of the electrical pixel response and optical qualities of the structure and is thus helpful. In some preferred embodiments the mirror comprises an aluminium mirror. Preferably the mirror comprises a stack or sequence of layers comprising aluminium and one or more other metals, for example TiW, optionally including one or more intermediate layers of amorphous silicon. Fabricating a mirror using such a stack helps to reduce stress and potential bowing of the mirror surface.

In diffractive optical applications it is often preferable to separate incident and diffractive light by angle, that is by illuminating the SLM at an angle to a normal to the substrate of greater than 0°, so that on average light is diffracted away at substantially the same angle to the normal. For example, the SLM may be illuminated at 45° so that it also reflects the diffracted light at 45°. It can be advantageous to have a square first diffraction order and therefore, in embodiments, the pixel pitch (distance between the centres of adjacent pixels) is preferably longer in one direction in the plane of the substrate (say the x-direction) than in a perpendicular direction in the plane of a substrate (say the y-direction), by a tilt factor greater than unity. For example for illumination at 45° the tilt factor is \sqrt{2}.

In a related aspect the invention provides a phase modulating spatial light modulator (SLM), the spatial light modulator comprising: a substrate bearing a plurality of SLM pixels, each of said SLM pixels comprising a MEMS (micro electromechnical system) optical phase modulating structure over CMOS pixel drive circuitry for the structure; wherein said MEMS optical phase modulating structure comprises: a pixel electrode coupled to said pixel drive circuitry for a pixel; a mirror spring moveable in a direction perpendicular to said substrate by an electric field applied by said pixel electrode; and a mirror mounted on said mirror-spring; and wherein a voltage is applied by said CMOS pixel drive circuitry to said pixel electrode flexes said mirror spring to translate said mirror perpendicularly to said substrate substantially without tilting.

In some preferred embodiments the mirror spring is electrically connected to a ground connection and the pixel electrode is connected to the CMOS pixel drive circuitry. In embodiments the drive circuitry is configured to apply a variable analogue drive voltage to the pixel electrode, to translate the mirror perpendicularly to the substrate to a variable analogue position.

In embodiments the mirror spring may be electrically connected to a metal layer of the CMOS pixel drive circuitry by one or more vias through the spring support structure or side-walls of the pixel.

### Spatial Light Modulator Fabrication

According to a related aspect of the invention there is provided a method of fabricating an optical phase modulating MEMS spatial light modulator, the method comprising: providing a substrate; depositing a sacrificial spring support structure on said substrate; providing a layer of spring material over said sacrificial spring support structure; patterning said layer of spring material to define a mirror spring supported by said spring support structure, wherein said mirror spring comprises a mirror support and a plurality of mirror spring arms each extending between said mirror support and said spring support structure, wherein each said mirror spring arm has a spiral or serpentine shape; forming a mirror mounted on said mirror support; and removing said sacrificial spring support structure.

One of the difficulties in fabricating a piston-type optical phase modulating MEMS device as previously described is fabrication of the mirror spring without this collapsing. This is especially difficult where the device is fabricated on a CMOS substrate, since deposition of single crystal or amorphous silicon is a high temperature process incompatible with CMOS. Embodiments of the above described method substantially facilitate fabrication of the mirror spring.

In some embodiments the sacrificial spring support structure comprises one or more walls or pillars, which may afterwards be removed by an undercut etch. In another potentially preferable, approach however the sacrificial spring support structure comprises amorphous carbon, which has the advantage that the sacrificial spring support structure can be a substantially solid and continuous support structure under the mirror spring until a final spring release stage.

In a still further approach the sacrificial spring support structure may comprise (silicon) oxide, which may afterwards be removed using a (vapour) hydrofluoric acid etch. Surprisingly it has been found that it is possible to perform such an etch even after fabrication of the (aluminium) mirror since, for reasons that are not fully understood, the hydrofluoric acid etch does not appear to significantly etch the mirror surface. This provides the advantage that the mirror can be fabricated over the spring support structure prior to releasing the structure, whereas if the structure had to be released first, fabrication of the mirror afterwards would be likely to cause collapse of the spring.

In a related aspect the invention provides a method of fabricating a MEMS device, the method comprising: providing a CMOS substrate; depositing at least one layer of amorphous carbon as a sacrificial layer; providing at least one layer of said MEMS device over said amorphous carbon layer; removing said sacrificial layer of amorphous carbon to fabricate said MEMS device.

In some preferred embodiments the method further comprises depositing a barrier layer in between the amorphous carbon and the MEMS device layer. Where the MEMS device layer comprises SiGe the barrier layer may comprise amorphous silicon, or less preferably, potentially aluminium. Use of such a barrier layer inhibits a deleterious interfacial reaction between the MEMS device layer and the amorphous carbon. Such a barrier layer may, however, not be needed if the MEMS device layer comprises a metal or metal alloy.

In embodiments of the method the layer of amorphous carbon may be patterned prior to providing the MEMS device layer over the amorphous carbon layer, for example, to define a via or trench down to an underlying layer. This can facilitate later deposition of material to fasten the MEMS layer to an underlying layer. Additionally or alternatively the amorphous carbon may be planarised and/or polished prior to providing the overlying MEMS layer.

The overlying MEMS layer may be provided by depositing a layer of material, for example, a layer of spring material such as a metal, metal alloy or SiGe. However in other embodiments of the method the MEMS layer is provided over the amorphous carbon layer by wafer bonding a silicon layer more particularly a silicon-on-insulator wafer over the amorphous carbon, with the silicon layer facing the layer of amorphous carbon. The back of the silicon-on-insulator wafer comprising a layer of oxide may then be removed to leave a silicon layer over the layer of amorphous carbon.

The amorphous carbon itself may either be deposited directly or a layer of photoresist (PR) may be converted to a layer of amorphous carbon. The skilled person will appreciate that amorphous carbon (aC) is neither graphite-like nor diamond-like, that is it does not consist purely of sp² or purely of sp³ hybridised bonds, but instead comprises a mixture of sp² and sp³ bonds.

Embodiments of the method may comprise depositing a second layer of amorphous carbon over the MEMS device layer, as a second sacrificial layer. In embodiments of the method the first MEMS layer may comprise a mechanical spring layer and may be used to fabricate a generally planar spring by defining arms of the spring whilst the layer is supported by the amorphous carbon. In an optical MEMS device the second sacrificial layer may be used to support a mirror layer for fabricating a mirror over the mechanical spring layer, vertically spaced away form the spring layer and attached to the spring, for example by a ‘stitch’ or via. After fabrication of such a device both the sacrificial layers of amorphous carbon may be removed, for example by ‘burning’ this off using an oxygen plasma etch or ashing process. The device may then be packaged, for example in the case of an optical device by hermetically sealing a window over the device onto the substrate by means of an adhesive.

In preferred embodiments the MEMS device is fabricated over a CMOS substrate carrying driver circuitry for the MEMS device, and the method includes exposing part of a top metal layer of the CMOS substrate prior to depositing the at least one layer of amorphous carbon. This exposed metal (which, optionally, may also be patterned) will become a or a set of drive electrodes for the device, for example a pixel drive electrode for a piston-type optical phase modulating MEMS device.

### BRIEF DESCRIPTION OF THE DRAWINGS

These and other aspects of the invention will now be further described, by way of example only, with reference to the accompanying figures, in which:

FIG. 1 shows a view from above and a vertical cross section view of a MEMS pixel mirror showing dimensions used for the development of a voltage-deflection relationship;

FIG. 2 shows a function expressing voltage, thickness and width tolerances as a function of gap height for an 8 nm resolution and 405.8 nm deflection−f(h 8 nm, 405.8 nm);

FIG. 3 shows cross-sectional and top views of a MEMS pixel (omitting the mirror in the top view) of (a) a 3 layer mirror/support structure with a solid plate electrode, and (b) a two layer mirror structure with the flexure as the electrode;

FIGS. 4a and 4b show, respectively, an example MEMS pixel with a three-layer mirror structure with a serpentine flexure (omitting the top optical surface), and a set of curves for the structure showing deflection versus voltage and tolerance (voltage, thickness and width);

FIGS. 5a to 5c show, respectively, a model of a MEMS pixel mirror as a damped harmonic oscillator where k is the flexure stiffness, m is the total mirror mass, b is the damping, and f is an applied force, for determining a mirror settling time. An illustration of squeeze film damping which occurs as air is pushed laterally during vertical deflection of the electrostatic gap; and an illustration of Poiseuille flow, which originates from viscous resistance of airflow through small cross-sections;

FIG. 6 illustrates example MEMS pixel structures with varying numbers of spiral arm turns or loops (where a loop is defined as a 360° rotation around the pixel perimeter), and corresponding deflection-voltage relationships, for an electrostatic gap of 1.8 μm;

FIGS. 7a to 7c show, respectively, an example of a two-beam flexure design with a 14 μm pixel pitch and a 1.6 μm capacitor gap; a corresponding voltage versus deflection characteristic; and an example cross-sectional view of a deflected mirror;

FIGS. 8a and 8b show, respectively, an example of a rectangularly shaped MEMS pixel with a rectangularly shaped flexure with two SCS (single crystal silicon) beams; and deflection-voltage curves comparing rectangular and hexagonal shaped two-beam designs;

FIGS. 9a and 9b show, respectively, a cross-sectional view of an example of a MEMS pixel with a stepped lower pixel electrode; and deflection versus voltage curves for the stepped electrode design with a range of capacitor gaps, illustrating that the stepped electrode increases deflection for a given applied voltage;

FIGS. 10a and 10b show, respectively, a top view of a rectangular flexure including portion bars towards the centre of the flexure (mirror mount), and a corresponding deflection-voltage characteristic;

FIG. 11 shows the top and side views of piston-type MEMS pixels with, respectively, a moving centre and fixed frame (upper) and a fixed centre and moving frame (lower);

FIG. 12 shows a 3D perspective view with cutaway portions of an optical phase modulating MEMS SLM according to an embodiment of an aspect of the invention;

FIG. 13 shows an enlarged portion of the structure of FIG. 12;

FIG. 14 shows a reduced version of the structure of FIG. 12, illustrating a field of hexagonal optical phase modulating piston mirrors;

FIG. 15 shows an example of a holographic image projection system in which the MEMS SLM of FIG. 12 may be employed;

FIGS. 16a to 16g show stages in a first embodiment of a fabrication process for the MEMS SLM of FIG. 12 according to an aspect of the invention;

FIGS. 17a to 17h show stages in a second embodiment of a fabrication process for the MEMS SLM of FIG. 12, and a variant of this, according to an aspect of the invention;

FIGS. 18a to 18j show stages in a third embodiment of a fabrication process of the MEMS SLM of FIG. 12 according to an aspect of the invention;

FIGS. 19a to 19j show stages in a fourth embodiment of a fabrication process of the MEMS SLM of FIG. 12 according to an aspect of the invention; and

FIGS. 20a to 20k show stages in a fifth embodiment of a fabrication process of the MEMS SLM of FIG. 12 according to an aspect of the invention.

### DETAILED DESCRIPTION

Some of the desirable requirements for an optical phase modulating MEMS spatial light modulator (SLM) are described below. The features described below are not essential but are desirable in an SLM for diffractive image display applications, in particular the holographic projector which we describe later. Thus, for example, in a conventional imaging system light loss is proportional to the square of the deadspace between pixels whereas in a diffractive imaging system this loss is approximately proportional to the fourth power of the dimension of the deadspace between pixels. Likewise the shape of the first diffraction order is dependent, in part, on the spatial Fourier transform of the pixel shape (although the pixel shape in the diffracted image is dependent on the Fourier transform of the outline of the pixel array). Further, since in general a MEMS SLM with piston-type mirror actuation will not rotate polarisation, instead the SLM may be mounted at an angle, for example 45°, to separate incident and diffracted light. Still further it is desirable for the SLM to produce a diffracted image which is large, which makes small pixels desirable—although it can also be useful if the drive electronics for a pixel fit underneath the pixel (though this is not essential).

Noting these desirable features, tilting the SLM at 45° increases the diffraction angle in the horizontal direction by \sqrt{2}, but leaves the vertical diffraction angle changed. To compensate for this, preferably the period of the pixel grid in the horizontal direction is scaled by the same \sqrt{2} factor. Further, it is preferable that the pixels are rectangularly spaced in the sense that the pixels have a regular spacing in the x- and y-directions in a lateral plane of the device. Different pixel shapes lead to different relative proportions of light diffracted into the desired first order (where the image is formed) as against higher diffraction orders (where any light is not usable and is therefore wasted). If the deadspace between pixels is small, this optical diffraction efficiency is optimised by near-diamond-shaped irregular hexagons, whereas if the pixel deadspace (that is the space between pixels is large), the perimeter/deadspace loss dominates and a pixel shape which is closer to a regular hexagon is desired to minimise the pixel perimeter (a regular hexagon has the lowest perimeter to area ratio of any tessellating shape).

As previously mentioned, small pixels are desirable for a number of reasons including that for a given resolution, lens clear apertures are reduced, making the system f/# lower, reducing aberrations and improving system tolerances; and because diffraction angles from the SLM are increased, decreasing lens powers required to achieve desired field magnifications in the optical system. In embodiments an electrostatically-actuated pixel of maximum lateral dimensions 10 μm×10 \sqrt{2} μm is desirable. Further details may be found in our patent application GB1019745.7 filed 22 Nov. 2010, which is hereby incorporated by reference in its entirety for all purposes.

A phase ramp or step in Fourier space corresponds to a position shift in image space and incorporating a phase ramp/step, preferably with a gradient chosen to shift the y-direction by a quarter of the field height, into the SLM pixel has the effect of shifting the diffraction pattern attenuation envelope (for examples a sinc envelope) away from a zero order spot and towards a centre of the displayed image. This decreases the attenuation caused by the diffraction attention envelope in the Y-direction and thus improves diffraction efficiency. Thus preferably a MEMS pixel mirror incorporates an out-of-plane relief structure (topography), for example a step such that one half of the pixel is raised above the other by a few 10 s of nm. In embodiments a binary phase step of approximately 30 nm is desirable. Our UK patent GB2454246 (U.S. Ser. No. 12/740,000) hereby incorporated by reference in its entirety for all purposes provides further details.

In preferred embodiments pixel mirror flatness is moderately well controlled, to reduce scatter, loss of contrast and the like. Using a mirror with an aluminium surface can provide a reflectivity of greater than 85% across the visible spectrum (430 nm to 660 nm); higher reflectivity can be achieved using a silver film, but suitable fabrication facilities are less common. As previously mentioned, it is important that the inter-pixel gap is reduced as far as practicable, to maintain diffraction efficiency.

In embodiments five bits of data are employed per pixel in order to provide 32 equally spaced phase steps of approximately 13 nm between 0 and approximately 406 nm. Assuming the stroke error has a Gaussian distribution, it is preferable that the standard deviation of stroke error is less than around +/−10 nm. In other arrangements the maximum stroke may be less, for example around 340 nm.

In a diffractive imaging system such as a holographic projector a proportion of defective pixels may be tolerated, for example up to 100 defective pixels. In one embodiment the MEMS SLM may have a resolution of 144×144 or 160×160 active pixels. To reduce scattering and ease optical design it is preferable to provide an ‘apron’ around the active addressable area of the SLM, for example an 80 pixel wide static apron or ribbon extending around the perimeter of the active portion of the SLM area. In embodiments the apron has a phase pattern, for example a pattern of two pixel heights a reference or base line height and a half-wavelength retardation height (for example 188 nm at a wavelength of 532 nm, in reflection mode at 45° illumination). The SLM may be provided with a black frame to inhibit extraneous light, and may optionally be mounted on a printed circuit board, for example FR4. In some preferred embodiments the SLM has a maximum height of less than 5 mm.

### SLM Design Process

### Deflection Versus Voltage

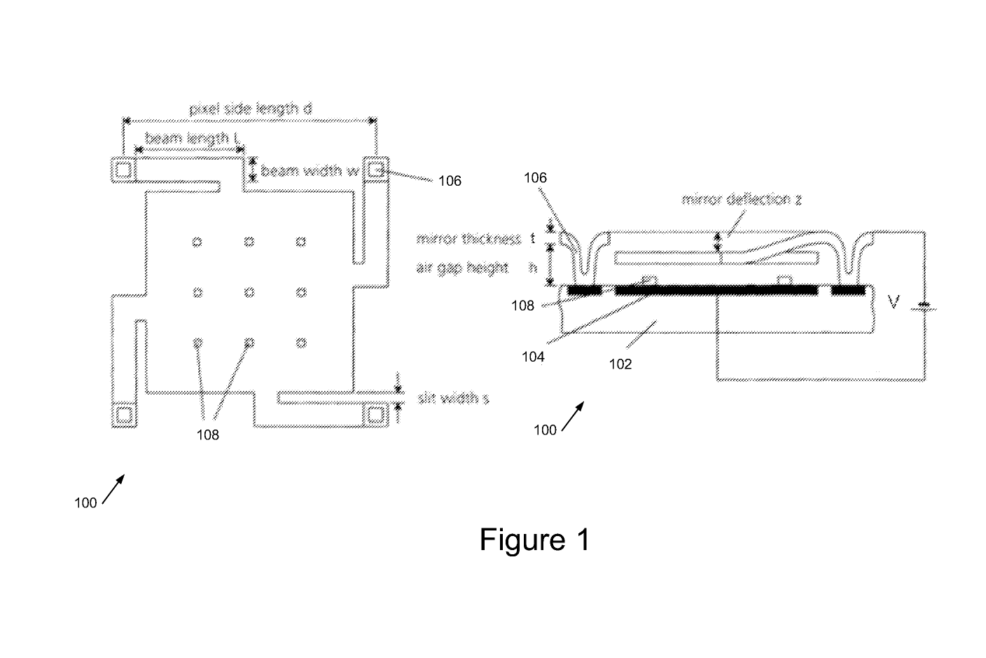

Downward deflection of the mirror is actuated by the electrostatic force across the capacitor gap, and the restoring force is provided by the elastic energy stored in the beam. The following analysis is developed for the illustrative example of the four-beam piston mirror 100 shown in FIG. 1. There is a potential applied between the center mirror surface and a fixed bottom electrode (denoted by the address voltage V); the mirror has pixel side length of d, beam (arm) length l, beam/arm) width w, mirror thickness t, (capacitor) air gap h, and slit width s. The mirror 100 has a substrate 102, address electrode 104, support posts 106, mirror stoppers 108, and etch holes 110.

If the mirror undergoes a vertical mirror deflection z, the total mechanical restoring force from bending of the four rectangular mirror beams is given by (this analysis does not yet include beam torsion):

$${F}_{Mechanial} = \frac{4 {Et}^{3}}{{L}^{3}} z \qquad ( 1 )$$

where E is beam modulus of elasticity (72 and 160 GPa for Al and (single crystal) Si, respectively), and t, w, and L are the beam thickness, width, and length, respectively. The effective beam stiffness—k—is the ratio of force to deflection and has units N/m.

The electrostatic force is calculated as the negative gradient of the stored electrical energy:

$${F}_{electrical} = - ∇ [ \frac{1}{2} {CV}^{2} ] = \frac{ɛ A}{2 {( h - z )}^{2}} {V}^{2} \qquad ( 2 )$$

where A is the area of the capacitor and c is the permittivity of free space. At a given operating point these forces are equal and the voltage as a function of deflection becomes:

$$V = \sqrt{\frac{8 {Ewt}^{3}}{ɛ {AL}^{3}}} ( h - z ) {z}^{1 / 2} \qquad ( 3 )$$

Since the mechanical restoring force is linear with deflection and the electrostatic force is inversely proportional to the gap, beyond a certain value of deflection (denoted zₚ) there is no longer a stable operating point and the actuator undergoes a “pull-in” phenomenon where the top plate spontaneously and fully deflects downward. At zₚ the derivative of deflection with respect to voltage is infinite:

$$\frac{dV}{dz} {\vert}_{z = {z}_{P}} = \frac{1}{2} \sqrt{\frac{8 {Ewt}^{3}}{ɛ {AL}^{3}}} {z}^{- 1 / 2} [ h - 3 z ] = 0 ⇒ {z}_{P} = \frac{h}{3} \qquad ( 4 )$$

This indicates that with voltage control, depending on the configuration, only a maximum of ⅓ of a given gap may be usable for analog deflection. In reality, to account for process imperfections, control voltage tolerance, and overshoot of the mirror step response, and to provide a safety margin, a gap of at least three or four times the desired deflection is preferred.

Using Equation (3), an 8 nm mirror deflection tolerance translates into process and voltage tolerances. We define a function f(h, dz, z) where h is the gap height, dz is the deflection accuracy, and z is the deflection:

$$f ( h , dz , z ) = ( \frac{h - 3 z}{h - z} ) \frac{dz}{z} \qquad ( 5 )$$

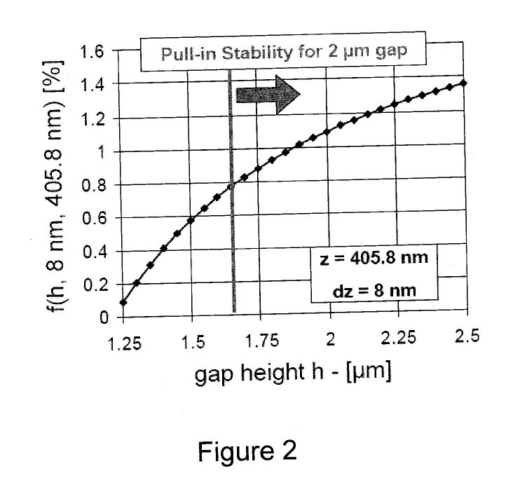

f (h, 8 nm, 405.8 nm) is plotted in FIG. 2; here 405.8 nm is the target maximum deflection. The voltage (V), beam thickness (t), and beam width (w) (or elastic modulus) tolerances are then expressed as:

$$\begin{matrix}\frac{dV}{V} = \frac{1}{2} f ( h , dz , z ) & ( 6 ) \\ \frac{dt}{t} = - \frac{1}{3} f ( h , dz , z ) & ( 7 ) \\ \frac{dw}{w} = - f ( h , dz , z ) & ( 8 )\end{matrix}$$

In one approach the mirror flexures may be composed of serpentine beams with a number of concentric turns. In this case, the torque T at corners or angles between sections of straight beams also contributes to the mechanical deflection.

$$T = \frac{GJ θ}{L} \qquad ( 9 )$$

where θ is the angle of twist and L is the beam length. The torsional rigidity GJ is given by:

$$GJ = \frac{1}{3} {t}^{3} wG ( 1 - \frac{192 t {\sum }_{n = 1}^{∞} tanh [ \frac{n π w}{2 t} ]}{w {π}^{5}} ) \qquad ( 10 )$$

The compliance of a given flexure is then calculated from the sum of flexural and torsional contributions.

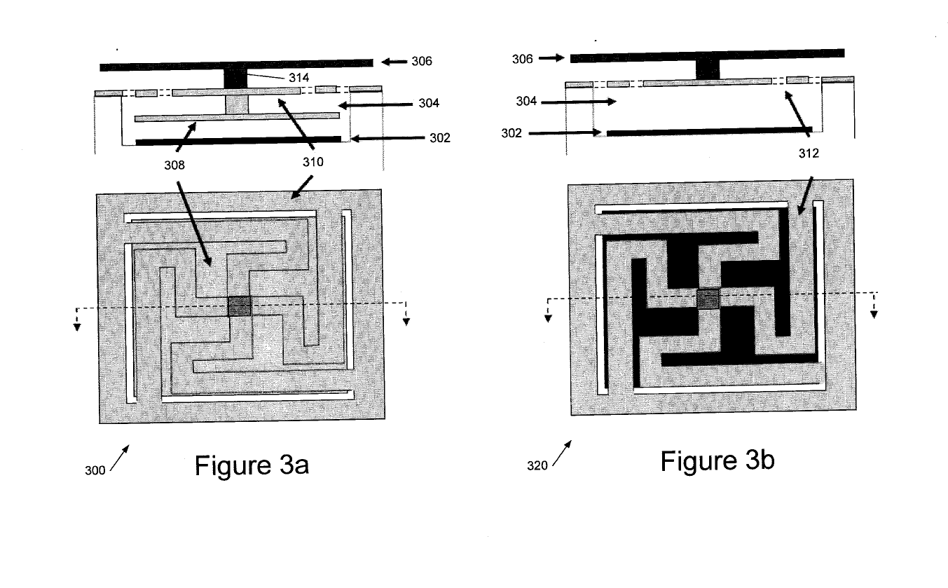

Referring now to FIG. 3, this shows examples of a MEMS SLM pixel 300, 320 with, respectively, a 3-layer and a 2-layer mirror/electrode/support structure. The structure comprises a fixed lower electrode 302 at the bottom of a cavity 304 in a CMOS wafer with an upper mirror 306 (not shown in the plan views). In the 3-layer structure a separate top electrode 308 and mirror spring (flexure) 310 is provided; in the 2-layer device the mirror spring (flexure) 312 also serves as the top electrode. In the 3-layer device the electrostatic force is applied to the most compliant centre region of the flexure (mirror spring) via a post 314 connecting the flexure and the solid plate electrode 308. In both approaches a separate optical (mirror) surface 306 is provided so that optimisation of this is decoupled from optimisation of the MEMS actuator.

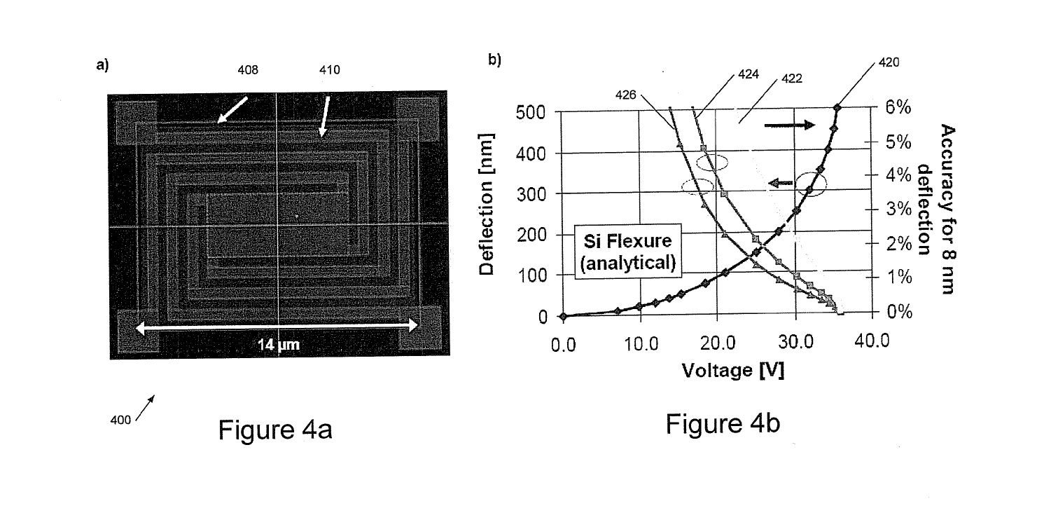

Referring now to FIGS. 4a and 4b, FIG. 4a shows a 3-layer type pixel structure 400 having a solid plate top electrode 408 and rectangular mirror spring (flexure) 410. The pixel pitch is 14 μm (an approximation for 10\sqrt{2}), the (capacitor) gap was 1.75 μm, the flexure beam thickness, space and pitch were 200, 500 and 500 nm, respectively, and the electrode plate area was 13.5×9.5 μm.

In FIG. 4b curve 420 refers to the left hand y-axis and shows the stroke in mm against applied voltage; curves 422, 424 and 426 refer to the right hand y-axis and show, respectively, deflection accuracy (error) against applied voltage for variations in beam width (or elastic modulus) 422, voltage 424, and beam thickness 426 (referring to equation (5) above, for a single crystal silicon flexure of flexure stiffness k_{Si}=1.86 N/m.

### Mirror Settling

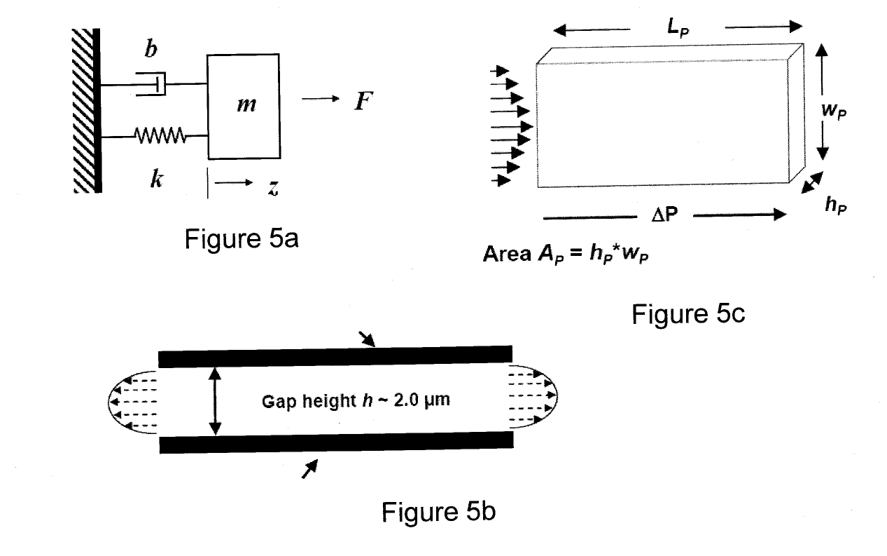

To determine the settling time the mirror may be modelled as a damped harmonic oscillator (FIG. 5a). In the Laplace domain, the transfer function relating an applied force (F) to deflection (z) is then:

$$\frac{z ( s )}{F ( s )} ∝ \frac{1}{{s}^{2} + \frac{b}{m} s + \frac{k}{m}} \qquad ( 11 )$$

where k is the stiffness, m is the total mass, and b is the damping. Taking the inverse Laplace transform and assuming the mirror is under damped, the time domain response of the mirror deflection exhibits the form of an exponentially decaying sinusoid:

$$\begin{matrix}z ( t ) ∝ {e}^{- \frac{b}{2 m} t} cos {ω}_{d} t where & ( 12 ) \\ {ω}_{d} = \sqrt{\frac{k}{m} ( 1 - \frac{1}{4 {Q}^{2}} )} & ( 13 )\end{matrix}$$

From equation (10), the settling time depends only on the mass and damping, and, assuming an error of 1% as settling, is calculated as:

$${t}_{settle} = - 2 * ln ( 0.01 ) \frac{m}{b} \qquad ( 14 )$$

The damping originates primarily from air flow around mirror surfaces and is composed of two elements—squeeze film damping and Poiseuille flow (see S. D. Senturia, “Microsystem Design”, Springer, 2004). In embodiments downward movement of the mirror causes air to flow up through the mirror spring and out through the gaps between the mirrors. As shown in FIG. 5b, squeeze film damping originates from the viscous drag of air opposing the vertical deflection of the mirror top electrode with respect to the bottom electrode. The damping coefficient has the functional form:

$$b ≅ \frac{96 η {L}_{s} {W}_{s}^{3}}{{π}^{4} {h}^{3}} \qquad ( 15 )$$

where η is the viscosity of air, Lₛ is the longer dimension of the electrostatic gap plate, Wₛ is the shorter dimension of the electrostatic gap plate, and h is the gap height.

Poiseuille flow originates from the viscous resistance of air flow through small cross-sections. Following FIG. 5c, a fluidic impedance R is defined as the ratio of the pressure drop ΔP to the flow Q.

$$R = \frac{Δ P}{Q} = \frac{12 η {L}_{P}}{{w}_{P} {h}_{P}^{3}} ≅ \frac{Δ F}{{A}_{P}} \frac{1}{{vA}_{P}} = \frac{b}{{A}_{P}^{2}} \qquad ( 16 )$$

where L_{P} is the length of the flow channel, hₚ is the smaller cross-sectional dimension of the channel, wₚ is the larger dimension of the channel, A_{P} is the area, and v is the flow velocity. The damping is then ˜R*A_{P}².

Considering Equation (12), the damping can place constraints on the total mirror mass.

The analytical approaches described above are helpful for understanding the operation of the pixel structure, but for more accurate results finite element analysis is preferred, in particular for a structure in which the mirror spring also forms the top electrode of a pixel, because of the complex electric fields produced by flexure of this structure. Although a 3-layer structure is expected to exhibit greater compliance, in part because the area of the top (flexure) electrode is larger, being a solid plate, and in part because the force is applied where the compliance is greatest, surprisingly finite element analysis shows that a 2-layer structure in which the mirror spring itself acts as the top (flexure) electrode provides good results, in part because the fringing fields around the spring arms increase the effective area of the electrode. Modelling of the electric field within a 2-layer type structure indicates that due to fringing fields the capacitance of the structure is about 25% higher than a parallel plate with an area equal to the bottom area of the beams (arms).

Whilst aluminium has advantages in increasing compliance because it is less stiff than single crystal silicon, aluminium alloys are susceptible to fatigue and creep and the inventors believe that overall the use of silicon or a material comprising silicon such as SiGe is preferable (the skilled person will appreciate that the use of SiGe, a silicon-germanium alloy, does not imply any particular molar ratio of silicon and germanium).

### Hexagonal Pixel Topologies

To achieve high compliance so that a pixel may be driven with a relatively low voltage, for example, less than 12 volts, a small spacing between beam arms is desirable, for example less than 500 nm and in embodiments around 200 nm. It is also desirable to avoid undesired parasitic resonant modes of oscillation of the mirror/mirror spring. Such modes may include a piston-type oscillation, tilt, in-plane translation, and in in-plane rotation. It is preferable to avoid such modes in the audio frequency range, and within a typical spectrum of ambient acoustic vibrations, typically low kilohertz frequencies. Finite element analysis can be used to predict such modes, but accurate modelling is difficult and thus it is also preferable to investigate the presence of parasitic resonances with experimentally fabricated test structures.

As previously mentioned, a small pixel pitch is desirable, but this in turn tends to make the mirror spring arms (beams) shorter which reduces compliance. Thus for a drive voltage of less than 12 volts the pixel spacing may be around 14 μm, although this may be reduced if higher drive voltages are available.

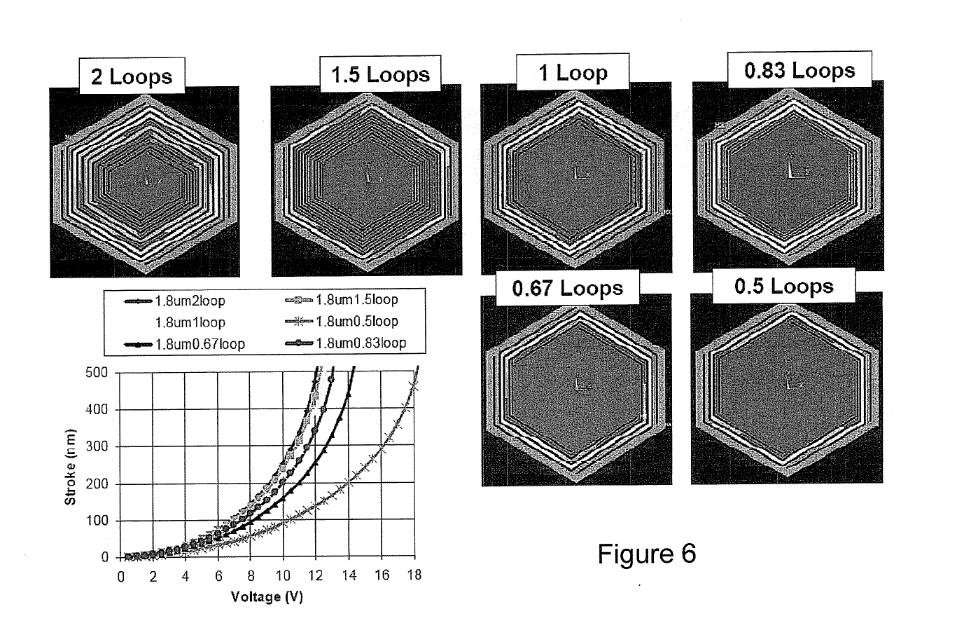

Referring now to FIG. 6, this shows examples of a mirror spring with mirror spring arms making a variable number of turns or loops of a spiral around the central mirror support, as illustrated at 0.5, 0.67, 0.83, 1.0, 1.5 and 2.0 loops. In the illustrated examples the electrostatic gap is 1.8 μm and the single crystal silicon beams have a width, space and thickness of 200 μm; the pixel pitch is 14 μm. FIG. 6 also shows the relationship between drive voltage and deflection in μm; it can be seen that as the number of beam or arm loops increases beyond 1.0 the incremental increase in deflection quickly saturates (in the graph 0.5, 0.67, 0.83, 1.0, 1.5 and 2.0 loops are indicated, respectively, by asterisks, triangles, circles, crosses, squares and diamonds). Thus it can be seen that the first loop provides the majority of the beam deflection; it can also be observed in the mirror spring topologies that one pair of beams has one more end than the other pair. To maximise damping, the centre plate of the mirror spring should be made as large as practicable. The electrostatic coupling between adjacent mirrors has been modelled and is found to be negligible.

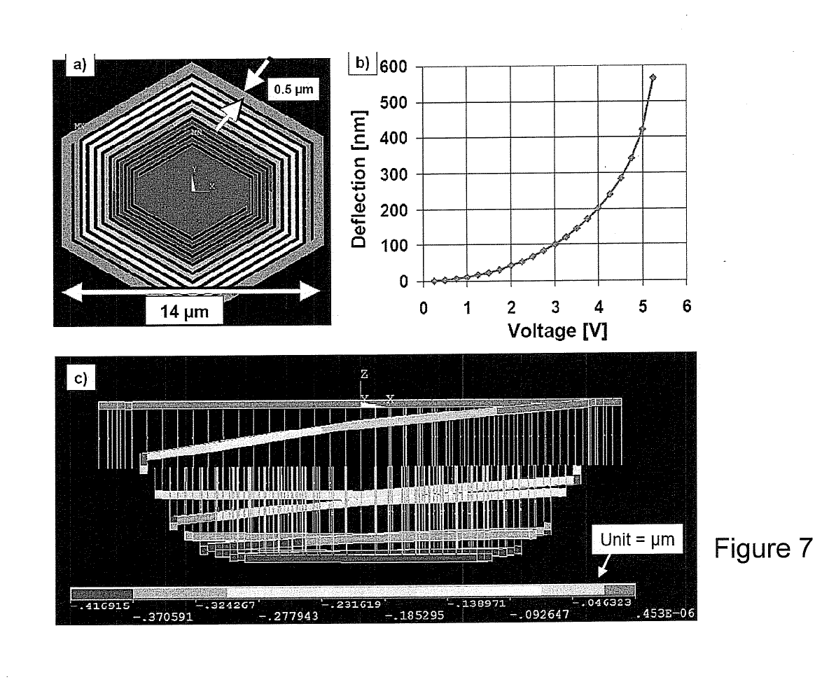

To increase compliance of the mirror spring (flexure) the number of beams can be reduced from 4 to 2 (because of a lack of 3-fold symmetry within an irregular hexagon or rectangular unit cell it is difficult to design a 3-beam flexure with high mechanical compliance). FIG. 7 illustrates that when the number of beams is reduced to two the compliance of the structure is significantly increased, albeit at the potential risk of introducing low-frequency tilt parasitic oscillation modes.

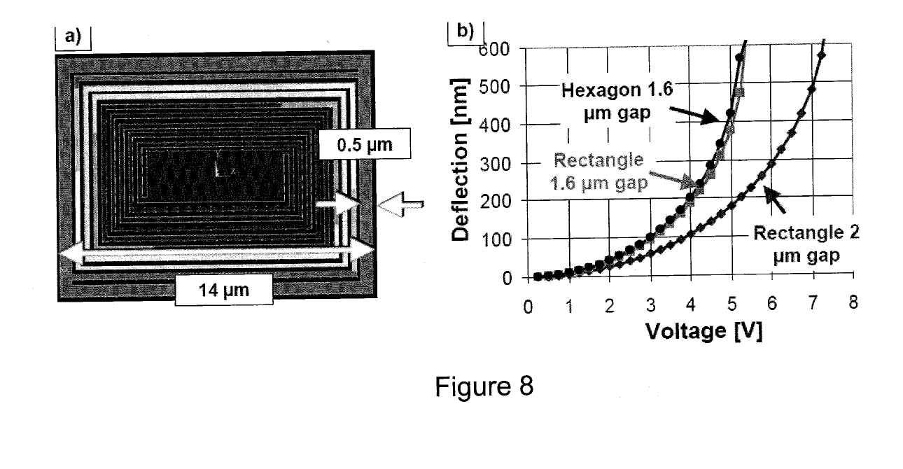

FIG. 8 compares the deflection-voltage characteristics of MEMS pixels with rectangular and irregular hexagonal mirror shapes, and it can be seen that the performance of these two different shapes is comparable from this perspective.

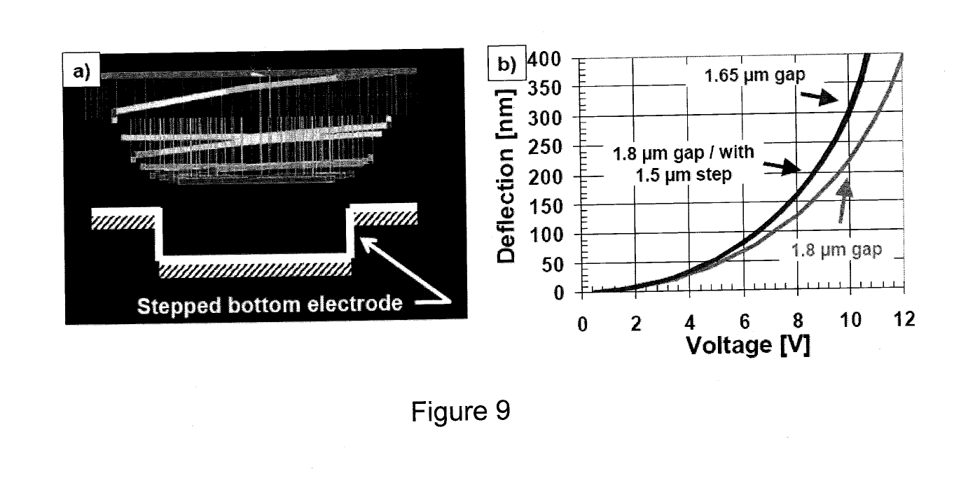

In embodiments the lower pixel electrode may be stepped or ramped so that the distance between the electrode and the mirror spring is greater in the centre of the pixel than towards the perimeter of the pixel. This can be used to increase the total deflection by providing the centre of the mirror, where the spring deflects most, with greater clearance, as illustrated in FIG. 9. Since the electrostatic force is inversely proportional to the square of the gap, subject to the previously mentioned constraints on pull-in it can be advantageous to reduce the size of the gap. In the example of FIG. 9 the gap around the perimeter of the pixel is 1.5 μm and the gap underneath the central mirror support plate of the mirror spring structure is 1.8 μm. As can be seen from the graph of FIG. 9b, this results in greater than 20% more deflection as compared with just a 1.8 μm gap, providing an effective compliance similar to that achieved with a 1.65 μm gap, but providing the mirror with more room, for example to overshoot during mechanical transience.

The transient response of a pixel has been found to be dominated by Poiseuille flow between the mirror spring arms, laterally between the mirror spring and the overlaying mirror, and vertically through the deadspace between mirrors. With the aforementioned structures the (1%) settling time is less than 20 μs.

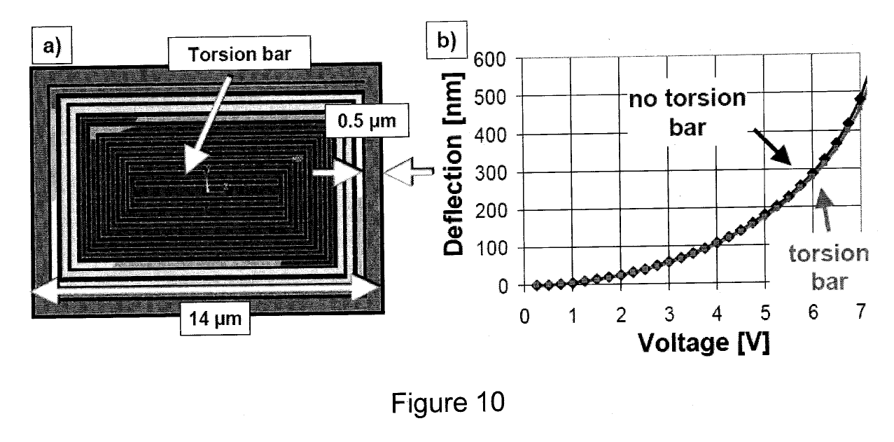

FIG. 10 illustrates a further alternative topology investigated to potentially increase compliance, in which the mirror spring arms incorporate one or more torsional bars connecting portions of the arms, observing that the absolute deflection of the interior turns of the flexure is relatively small, but that this region generates a net moment that induces deflection in the outer turns of the flexure. However the graph of FIG. 10b indicates that torsional bars do not significantly increase compliance in the test structure.

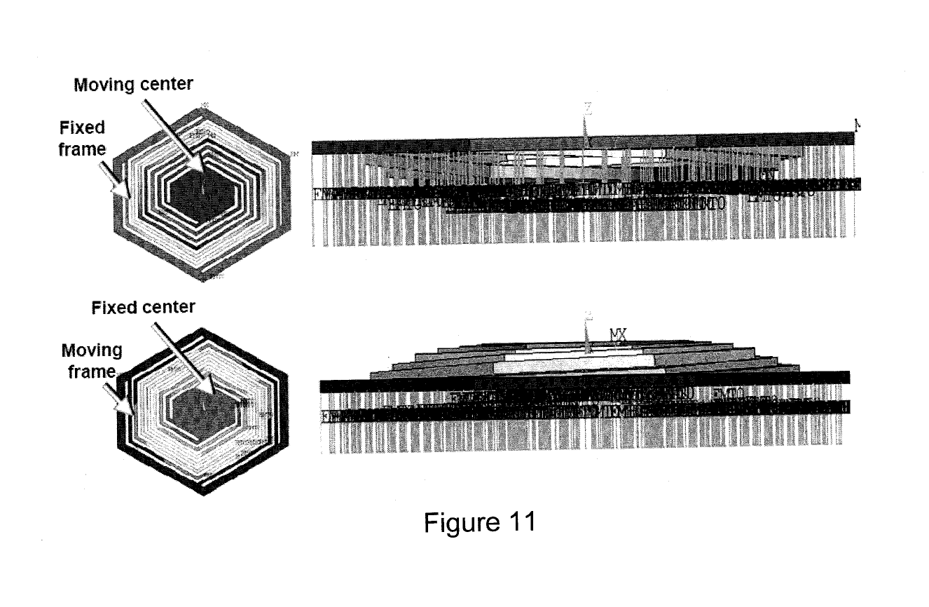

FIG. 11 shows alternative approaches for supporting the mirror spring, either at the perimeter of a pixel cell, or in the centre. Fixing the centre of the mirror spring support results in more deflection for a given voltage and could allow multi-point mirror attachment which could mitigate optical surface curvature. However such an arrangement is difficult to manufacture and could be susceptible to cross-talk.

Broadly speaking preferred embodiments of the mirror employ aluminium, although higher reflectivity can be achieved using silver. A mirror deadspace between pixels may be of order 500 nm, noting that in embodiments of the fabrication process sacrificial polymer is removed through the mirror inter-pixel deadspace. Optionally the mirror surface may include a 30 nm step. In embodiments the fabrication process may leave a dimple in the centre of each pixel approximately 1 μm wide and up to 1 μm deep. It is desirable to reduce mirror cupping which can result from residual stress in one or more of the layers from which the mirror is constructed. The apron around the SLM pixel array may be produced by a 190 nm aluminium film deposited in a tessellated irregular-hexagon pattern matching that of the pixel mirrors.

The SLM may be packaged using a hermetic glass sealing process with nitrogen and argon ambient gas at a pressure around 1 atm. An anti-reflection coated glass lid may be employed.

### Preferred Embodiment of an Optical Phase Modulating MEMS SLM

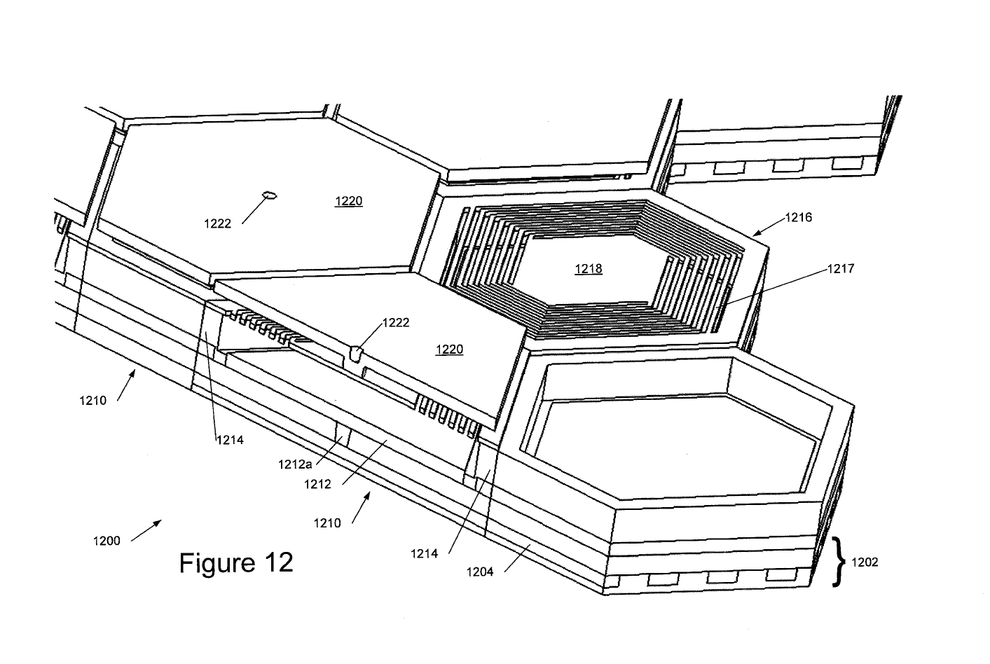

FIG. 12 shows a preferred embodiment of an optical phase modulating MEMS SLM 1200 resulting from the above described design process. Each electrostatically-actuated pixel is approximately 10×10 \sqrt{2} μm and deflects over 400 nm when actuated with 12 volts, has 8 nm of deflection resolution, settles within 30 μs, and has the shape of an irregular hexagon. The mirror spring comprises a single crystal silicon (SCS) electromechanical flexure serving as both a spring/mirror mount and as a top electrode.

Thus, continuing to refer to FIG. 12, in preferred embodiments the SLM 1200 comprises a substrate 1202 bearing a plurality of SLM pixels 1210. For display devices, individual addressing of mirror actuators is generally desirable, and this may be achieved by incorporating CMOS circuitry underneath each actuator. Thus substrate 1202 is preferably a CMOS substrate and a bottom pixel electrode 1212 may comprise a portion of an exposed top metal layer of the CMOS substrate with a via 1212a connection to one or more underlying metal layers 1204 of the CMOS substrate.

A MEMS pixel 1210 also comprises a spring support structure 1214, as illustrated an oxide wall, around the perimeter of the bottom pixel electrode 1212. The spring support structure 1214 supports a mirror spring 1216 comprising a mirror support 1218 and a plurality of mirror spring arms 1217 each extending between mirror support 1218 and the spring support structure 1214. In the preferred embodiment illustrated each mirror spring arm has a spiral shape. The mirror spring 1216 is electrically conductive and acts as a second, top electrode of the MEMS pixel structure. In operation a voltage applied between the bottom 1212 and top 1216 pixel electrodes generates an electrostatic force which results in translation (piston-type motion) of the mirror support 1218.

The pixel further comprises a mirror 1220 mounted on the mirror support 1218 and attached to this support by a ‘stitch’ or via (which leaves a dimple artefact 1222 in the centre of the mirror). In embodiments the mirror spring 1216 may optionally be attached to the substrate or spring support structure by another ‘stitch’ or via (not shown in FIG. 12). For example where the mirror spring comprises SiGe, the SiGe may be deposited into a trench extending down to the underlying silicon substrate.

When fabricating the structure of FIG. 12, the CMOS drive circuitry is constructed first and the MEMS actuator afterwards, and thus the MEMS fabrication should be compatible with CMOS, in particular processing temperature limitations (a maximum processing temperature of 425° C.). The mirror spring should exhibit good mechanical reliability and preferably its properties should not change significantly in 10¹⁰ or more cycles. Most metals and metal alloys do not satisfy these desirable requirements and whilst silicon based films such as polysilicon can exhibit this level of mechanical reliability, polysilicon requires high deposition temperatures which are incompatible with the CMOS temperature requirements.

Silicon (Si) germanium (Ge) alloys, in particular compositions having a high germanium content, for example greater than 65%, can have low deposition temperatures (down to 370° C.) and excellent mechanical properties that include low stress and low creep. High electrical conductivity can also be obtained with SiGe alloys, either with n-type or p-doping.

The preferred microstructure for mechanically reliable SiGe films is polycrystalline microstructure or a mixture of amorphous and crystalline phases.

A preferred deposition method for deposition of SiGe films is chemical vapour deposition (CVD) from silane and germane. An alternative deposition method for these films is plasma enhanced chemical vapour deposition (PECVD). This can be performed at even lower deposition temperatures than CVD although the mechanical properties are not as favourable as for CVD films.

Electrostatic actuators using SiGe alloys as the functional material are compatible with fabrication of the CMOS substrate first, and also are able to provide the other desirable properties for display applications mentioned above.

In one approach polycrystalline SiGe is deposited at, for example, 385° C. or less over a silicon seed layer (provided from a disilane deposited film). Optionally annealing such as laser annealing may be employed to reduce grain size and RMS roughness. Another less preferable option is to use polycrystalline germanium, which can self-anneal, but this material is less stable over time and also prone to attack by moisture. A further possibility is to employ an amorphous silicon mirror spring optionally again with a laser or low temperature annealing process.

In embodiments of the SLM one or more of the pixels may be replaced by a photodiode, to facilitate in-plane sensing of a spatial intensity profile of a light beam illuminating the SLM. This is feasible in a diffractive imaging system because in such a system a small number (up to around 1%) of inactive SLM pixels does not produce visible defects in the reproduced image. Such a photodiode may be fabricated on the CMOS substrate and provided with an opening over the photodiode to permit the ingress of incident light. Such photodiodes may be spatially distributed throughout the array: if a Gaussian intensity profile is assumed for an illuminating beam then, in principle, only 6 parameters need be determined to characterise the beam profile. For further information reference may be made to our earlier patent application GB1019749.9 filed 22 Nov. 2010, which is hereby incorporated by reference in its entirety for all purposes.

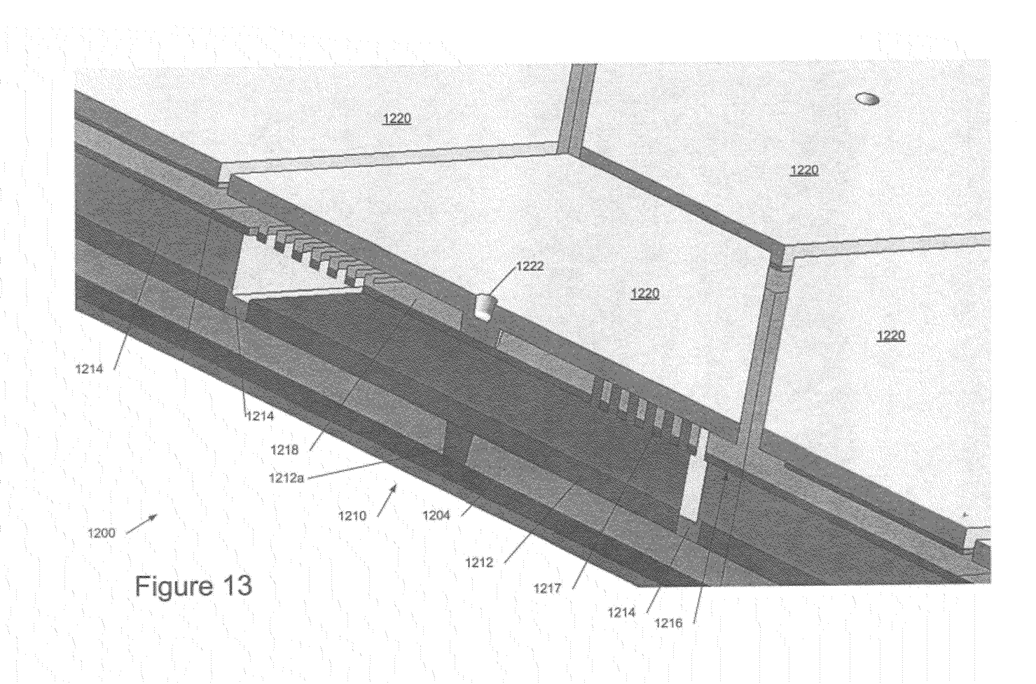

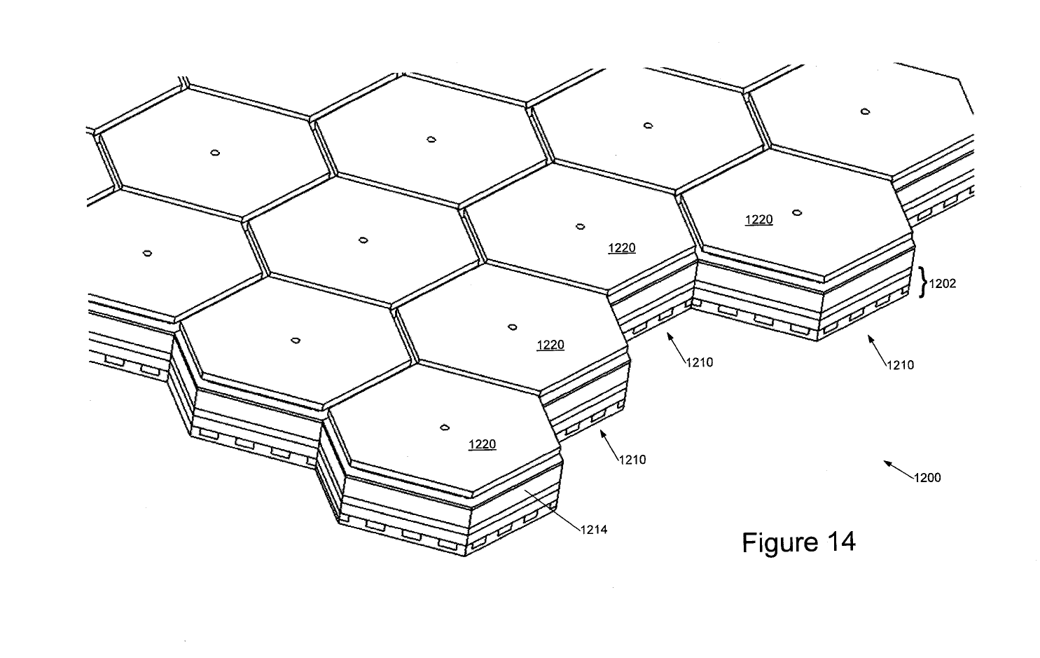

FIGS. 13 and 14 show alternative views of the optical phase modulating MEMS SLM 1200 of FIG. 12, and like elements are indicated by like reference numerals.

### Example Optical System

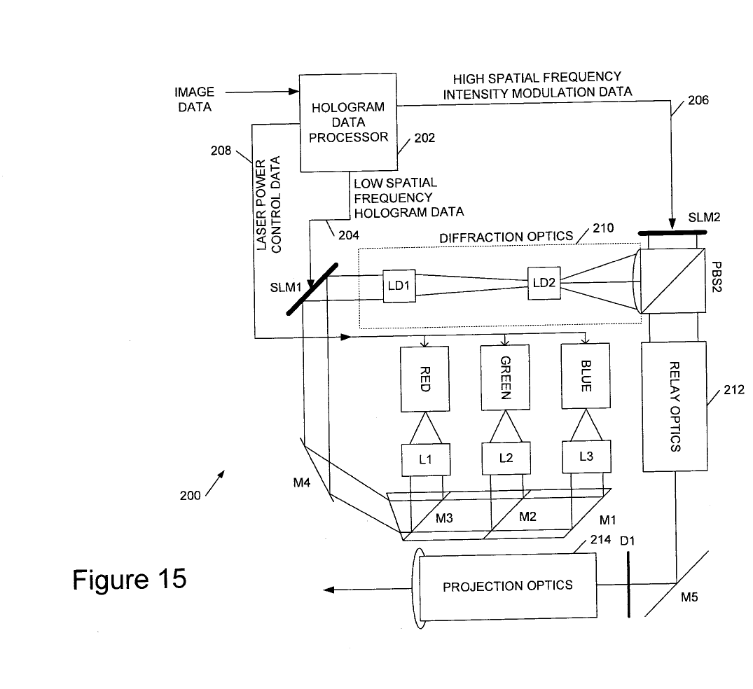

FIG. 15 shows an example of a diffractive (holographic) image projection system 200 for projecting an image onto a 2D screen, in which the SLM 1200 may advantageously be employed.

The architecture of FIG. 15 uses dual SLM modulation—low resolution phase modulation and higher resolution amplitude (intensity) modulation. This can provide substantial improvements in image quality, power consumption and physical size. The primary gain of holographic projection over imaging is one of energy efficiency. Thus the low spatial frequencies of an image can be rendered holographically to maintain efficiency and the high-frequency components can be rendered with an intensity-modulating imaging panel, placed in a plane conjugate to the hologram SLM. Effectively, diffracted light from the hologram SLM device (SLM1) is used to illuminate the imaging SLM device (SLM2). Because the high-frequency components contain relatively little energy, the light blocked by the imaging SLM does not significantly decrease the efficiency of the system, unlike in a conventional imaging system. The hologram SLM is preferably be a fast multi-phase device, for example a pixilated MEMS-based piston actuator device.

In FIG. 15:
SLM1 is a pixilated MEMS-based piston actuator SLM as described above, to display a hologram—for example a 160×160 pixel device with physically small lateral dimensions, e.g. <5 mm or <1 mm.
L1, L2 and L3 are collimation lenses (optional, depending upon the laser output) for respective Red, Green and Blue lasers.
M1, M2 and M3 are dichroic mirrors a implemented as prism assembly.
M4 is a turning beam mirror.
SLM2 is an imaging SLM and has a resolution at least equal to the target image resolution (e.g. 854×480); it may comprise a LCOS (liquid crystal on silicon) panel.
Diffraction optics 210 comprises lenses LD1 and LD2, forms an intermediate image plane on the surface of SLM2, and has effective focal length f such that fλ/Δ covers the active area of imaging SLM2. Thus optics 210 perform a spatial Fourier transform to form a far field illumination pattern in the Fourier plane, which illuminates SLM2.
PBS2 (Polarising Beam Splitter 2) transmits incident light to SLM2, and reflects emergent light into the relay optics 212 (liquid crystal SLM2 rotates the polarisation by 90 degrees). PBS2 preferably has a clear aperture at least as large as the active area of SLM2.
Relay optics 212 relay light to the diffuser D1.
M5 is a beam turning mirror.
D1 is a diffuser to reduce speckle.
Projection optics 214 project the object formed on D1 by the relay optics 212, and preferably provide a large throw angle, for example >90°, for angled projection down onto a table top (the design is simplified by the relatively low entendue from the diffuser).

The different colours are time-multiplexed and the sizes of the replayed images are scaled to match one another, for example by padding a target image for display with zeros (the field size of the displayed image depends upon the pixel size of the SLM not on the number of pixels in the hologram).

A system controller and hologram data processor 202, implemented in software and/or dedicated hardware, inputs image data and provides low spatial frequency hologram data 204 to SLM1 and higher spatial frequency intensity modulation data 206 to SLM2. The controller also provides laser light intensity control data 208 to each of the three lasers. For details of an example hologram calculation procedure reference may be made to WO2010/007404 (hereby incorporated by reference in its entirety for all purposes).

### MEMS SLM Fabrication

As previously mentioned, relatively low voltage operation is desirable (this also facilitates incorporating the CMOS pixel drive circuitry underneath a pixel since the size of the ‘high voltage’ transistors employed is reduced). As previously mentioned, to achieve this it is desirable that the mirror spring be compliant rather than stiff, but a difficulty with this is that the etched springs tend to fall into the pixel cavity. We will now describe some fabrication processes which address this difficulty.

Some preferred embodiments of the fabrication processors employ amorphous carbon as a sacrificial material, but this is not essential and we will also describe some alternative processors which employ supporting sacrificial walls which may be formed during the process for forming a cavity over which the spring is supported. We will also describe two different categories of process for forming the mirror spring layer, one in which the spring material, for example SiGe, is deposited, another in which a silicon-on-insulator wafer is wafer bonded ‘upside down’ onto the cavity walls (spring support structure), that is with the upper silicon layer of the Sol wafer towards the CMOS substrate, and then in embodiments afterwards thinned to remove the back of the SoI wafer to leave what was formerly the top (single crystal) silicon layer to be patterned to form the mirror spring.

### Amorphous Carbon for MEMS Fabrication

In some embodiments of the fabrication process amorphous carbon films deposited by PECVD are used as a sacrificial material for the fabrication of micro-electro-mechanical systems (MEMS).

Amorphous Carbon film properties provide the following characteristics: a range of intrinsic stress values from very tensile to very compressive. A bi-layer “building block” film which allows depositions of arbitrary thickness with low total stress (typical target thickness from 0 to 2 μm). Wet solvent resistance to facilitate the employment of traditional CMOS cleans. Easy removal of films by plasma ashing or other dry chemical processes. Potential to modulate the hardness of the Amorphous Carbon to facilitate chemical mechanical polishing. Potential to execute a low temperature fusion bond of Silicon on Insulator (SoI) to the polished Amorphous Carbon. These properties facilitate the fabrication of the MEMS designs in several ways.

When properly deposited, amorphous carbon is robust enough for thermal processes up to and beyond the maximum temperature tolerance of traditional CMOS devices (430° C.). This broadens the available choice of structural thin film materials with which to fabricate a device, including LPCVD (low pressure CVD) furnace based materials, PECVD based dielectric and semiconductor materials, and PVD (Physical Vapour Deposition) based metals, to name some examples.

The gap-fill behaviour of the a-C films, along with the ability to planarise the films through CMP (Chemical Mechanical Polishing) facilitates the production of flat surfaces. This in turn improves the planarity and surface roughness of the semiconductor/dielectric/metal films comprising the MEMS structures. If further improvement of the top surface of deposited films is desired, the robust mechanical nature of the underlying a-C sacrificial film facilitates chemical mechanical polishing of the deposited films without risk of damage to either the film itself or the previously fabricated structures which exist in the layers beneath it.

Additionally, the near-atomically smooth nature of the polished a-C surface allows for the possibility of employing SOI as a structural material layer for subsequent MEMS through fusion bonding.

After the various dry etching processes typically employed in device fabrication are completed (the high optical absorption of a-C facilitates lithography), the a-C material “locks” the patterned permanent structures in place. This characteristic, along with the wet chemical/solvent resistance of the a-C film allows for post-etch cleaning processes to be performed on the wafer without stiction or other damage occurring to the active MEMS structures.

Finally, the “ashability” of the a-C layers allows for the release of a near arbitrary arrangement of MEMS structures fabricated on multiple such sacrificial layers. Line/Space rules for these patterned structures that are considered to be quite aggressive by existing MEMS standards, such as 0.2 μm/0.2 μm are perfectly acceptable for release by commonly available CMOS dry ashing processes. Such dry processes provide substantially no risk of stiction or capillary force damage that can occur with other MEMS release methods.

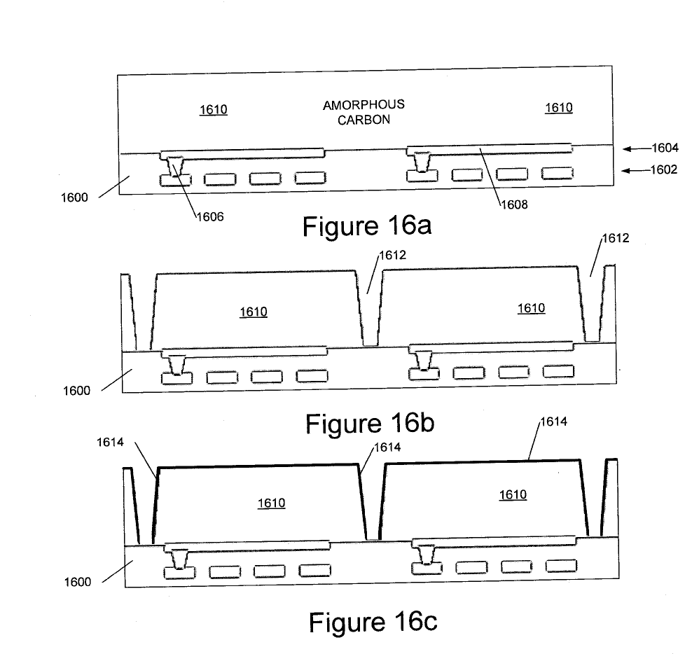

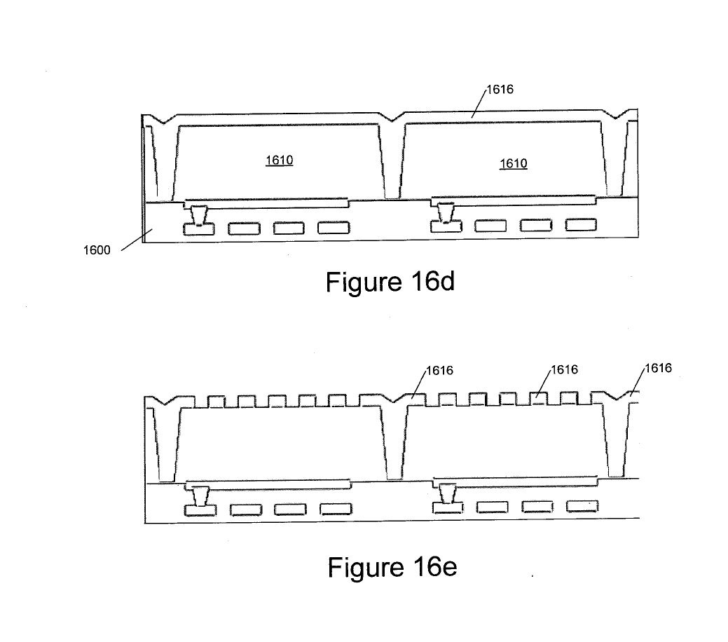

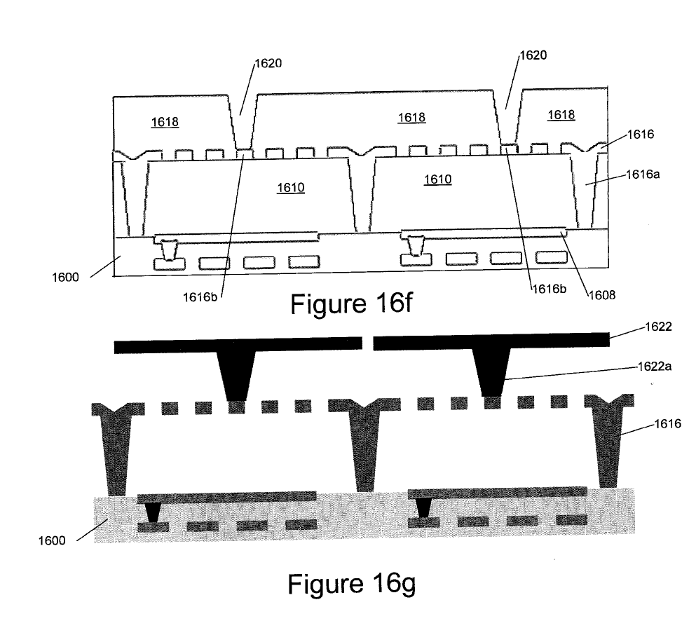

Referring first to FIG. 16a, this shows a CMOS substrate 1600 comprising a plurality of metal layers 1602, 1604 and vias 1606, in which a portion of the top metal layer 1604 has been exposed by removing interlayer dielectric (ILD)/nitride passivation and patterned to form a (bottom) pixel electrode 1608 of the MEMS cell. It is not necessary for the pixel electrode to be flush with the surrounding oxide.

A layer of amorphous carbon 1610 has been deposited over the substrate, for example by PECVD (plasma enhanced chemical vapour deposition). This may have a thickness of greater than 0.5 μm up to, for example 2 μm or 3 μm, more typically in the range 1-2 μm. This is to provide sufficient depth in the MEMS cell for the mirror spring to translate vertically without snapping onto the bottom pixel electrode. As previously described, this suggests a gap (layer thickness) of approximately 3 times the mirror (spring) stroke together with a safety margin. For example for a 500 nm stroke the gap (layer thickness) may be approximately 1.8 μm (3×500 nm+a 300 nm margin) so that the mirror spring does not attach to the bottom pixel electrode at the highest applied voltage, for example 12 volts. The layer of amorphous carbon 1610 serves as a first layer of sacrificial (SAC) material.

Referring now to FIG. 16b, the amorphous carbon 1610 is then patterned to form trenches 1612, for example by means of photoresist and reactive ion etching (RIE). The patterned surface is then cleaned to remove residual organics.

Then (FIG. 16c) a barrier layer 1614 is deposited over the amorphous carbon, in embodiments comprising 1 or 2 layers of amorphous silicon deposited by PECVD. This is to inhibit reaction of later deposited SiGe with the amorphous carbon surface. In embodiments the barrier layer 1614 is thin so that it does not significantly affect the spring constant of the later deposited SiGe, for example, around 300 angstroms (that is in embodiments around 10% of the thickness of the SiGe layer).

Next shown, as shown in FIG. 16d, a layer of SiGe 1616 is deposited. The thickness of this layer depends upon the desired spring constant but in embodiments may, for example, be of order 2,600 angstroms. As can be seen, the spring layer 1616 extends down through the trenches to contact the underlying CMOS substrates 1600, thereby attaching the spring layer to the substrate. Although SiGe is a preferred spring material, in variations of the process metal alloy may alternatively be employed.

FIG. 16e shows patterning of the spring layer 1616, for example using DUV (deep ultra violet) 248 nm lithography to define a spiral spring. Then (FIG. 16f) a second sacrificial layer 1618 is deposited over the patterned spring layer 1616, and itself patterned to define trenches 1620 down to the spring layer. The patterned spring layer defines a mirror spring supported by a spring support structure that is in this example the part of the deposited spring layer (‘stitch’ 1616a) which extends down to the CMOS substrate. The mirror spring comprises spiral mirror spring arms connected to a central mirror support 1616b, and the trenches 1620 extend down to this mirror support as these define the stitch or post by which the mirror will be attached to the mirror spring.

The thickness of the second sacrificial layer 1618 defines the height of the mirror and the length of the mechanical interconnect to the spring, and since in the final structure (FIG. 16g) the mirror extends beyond the mirror spring arms and over the spring support structure, the mirror height above the mirror spring should provide sufficient clearance for the mirror not to hit the spring support structure when the spring is at its closest design distance from the bottom pixel electrode 1608, with some margin for over travel. Thus, for the aforementioned example of a 500 nm spring stroke, the thickness of layer 1618 should be approximately 0.5 μm, with a small additional margin to allow for overtravel of the spring.

In one embodiment of the process the second sacrificial layer 1618 comprises i-line (265 nm photoresist, which is patterned to define trenches 1620 for the ‘stitch’ to the mirror, and UV cured. In embodiments of the process the mirror stack is deposited by physical vapour deposition and the mirror is chemically cleaned, so it is preferable to ensure that the sacrificial photoresist layer 1618 is robust, and thus it is preferable to subject this layer to a post-exposure bake, for example at 130-150° C., to identifuy this layer and increase its chemical resistance; it may also be subjected to additional UV curing to increase cross-linking within the polymer. In alternative embodiments of the process the sacrificial layer 1618 may comprise amorphous carbon, patterned and etched to form trenches 1620 as previously described for layer 1610.

Then (FIG. 16g) the mirror stack 1622 is deposited and patterned. In embodiments the mirror stack comprises a sandwich stack of materials, which reduces surface roughness and internal stress, the stack comprising amorphous silicon and having a top, reflective layer of aluminium (although other materials, for example silver, may alternatively be employed). In a preferred embodiment the mirror stack 1622 comprises a bottom layer of TiW or thickness 600 angstroms, followed by an amorphous silicon layer of thickness 3,000 angstroms, followed by a further TiW layer of 600 angstroms, and an upper reflective layer of aluminium of thickness 500 angstroms, all deposited by PVD. This mirror stack is then patterned to define hexagonal mirrors as shown, for example, in FIGS. 12 to 14. As can be seen from FIG. 16g, deposition of the mirror stack includes deposition of material into trenches 1620 to define a mirror stitch or post 1622a mechanically connecting the mirror 1622 to the mirror support part 1616b of the mirror spring 1616. The PVD deposition process results in a central mirror dimple 1222 as previously mentioned. The mirror may be patterned by a metal etch process.

Once the mirror stack has been deposited and patterned all the sacrificial material, that is layers 1610 and 1618, is removed, for example using an oxygen ashing process, and the structure is cleaned. The ashing process may employ oxygen in combination with water vapour and/or nitrogen, using a gentle cycle (no RF) of 60-90 seconds. This leaves the final structure shown in FIG. 16g, which illustrates a vertical cross-section through an optical phase modulating MEMS SLM of the type shown in FIGS. 12-14.

One advantage of the above described process is that the MEMS structures are only released at the end of the process, and thus the structure is supported throughout the fabrication process. One potential drawback is stress/stress gradient in the deposited spring layer 1616 and we will now describe some alternative processes which employ a wafer bonding/thinning process to provide a single crystal silicon spring.

In embodiments of the processes we now describe (silicon) oxide may be employed as a sacrificial material instead of amorphous carbon or photoresist. Likewise oxide may be employed as a sacrificial material in the process described with reference to FIG. 16, for example TEOS (tetraethoxysilane) or other oxide. Where in the process of FIG. 16 oxide is employed as a sacrificial material, this may be removed in the final step by using an anhydrous HF (hydrofluoric acid) vapour, or a liquid etch. Surprisingly this does not appear to etch the aluminium mirror surface.

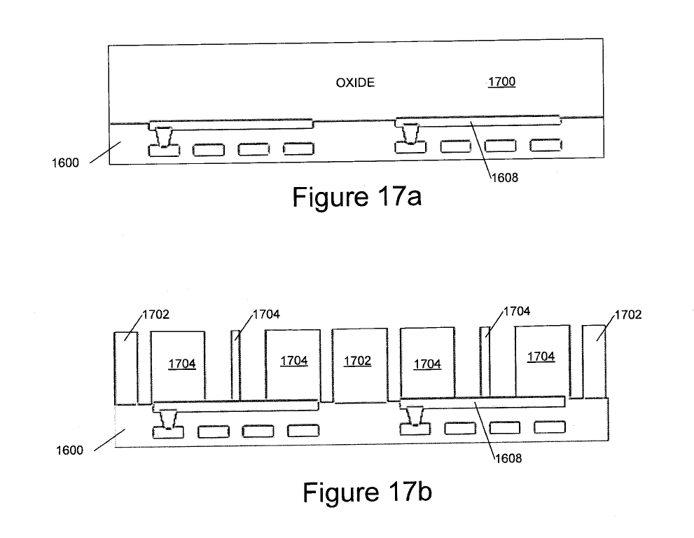

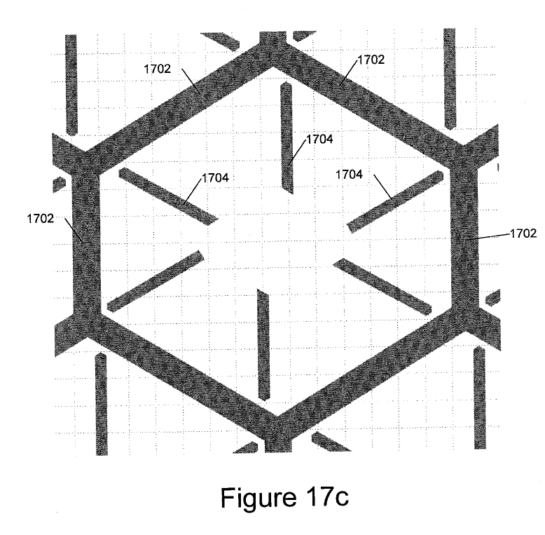

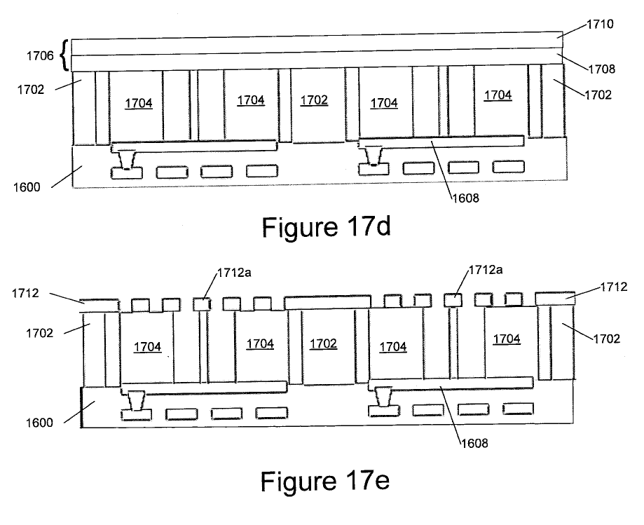

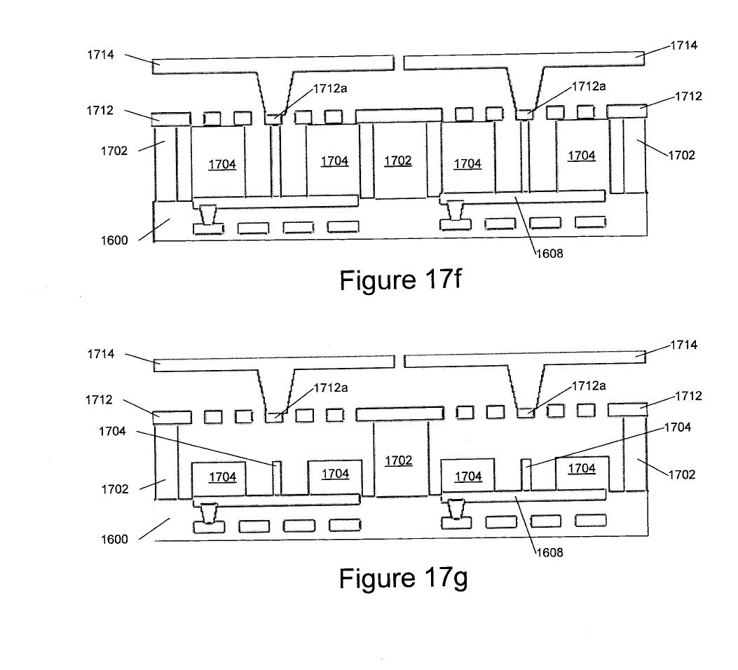

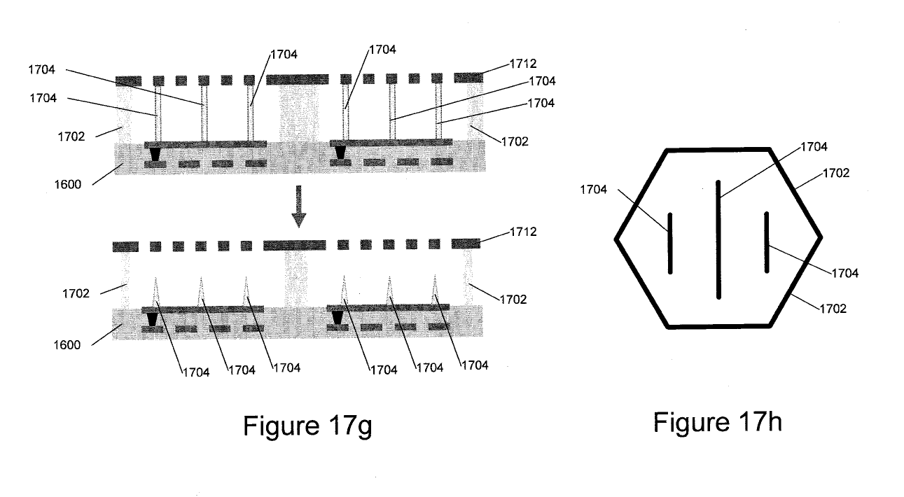

Referring now to FIG. 17a, this shows a CMOS substrate 1600 with a pixel electrode 1608, which corresponds to that shown in FIG. 16. However, in FIG. 17a an oxide layer 1700 is deposited over the CMOS substrate, cleaned, and planarised. The thickness of the oxide layer may be similar to that described for the FIG. 16 process, for example in the range 1-2 μm. Then (FIG. 16b) this oxide layer is patterned and etched, for example using RIE, to define a perimeter wall 1702 for each MEMS pixel cell to act as a spring support structure in the final device, and a set of internal sacrificial walls 1704 used to support the mirror spring during the mirror spring fabrication process. FIG. 17c, shows schematically, a planned view of the structure of FIG. 17b. In a variant of this process amorphous carbon may be employed to form the sacrificial walls 1704 rather than defining them in the oxide layer 1700.

Having formed the spring support structure and a set of internal sacrificial spring support structures, FIG. 17d shows bonding of a silicon-on-insulator wafer 1706 on top of the structure of FIG. 17b, the SoI wafer comprising a layer of crystalline silicon 1708, for example of thickness 0.2 μm, and an oxide layer 1710. After SoI wafer 1706 is bonded to the structure of FIG. 17b, the structure is annealed and then the buried oxide layer 1710 (and handling wafer, not shown) are removed, for example using a precision wet grinding process followed by a selected etch of the silicon handling wafer which stops on the buried oxide and then a selective etch of the buried oxide 1710 which stops on the silicon 1708. this leaves the structure of FIG. 17b with a thin single crystal silicon layer 1708 on top ‘tacked’ to the ‘spring support’ walls 1702. This single crystal silicon layer 1708 is then patterned (for example using DUV lithography) and then etched to define a mirror spring 1712 ‘tacked’ to the spring supporting walls 1702, defining a set of spiral mirror spring arms connected to a central mirror support 1712a.

As can be seen in FIG. 17e, the sacrificial walls 1704 support the mirror spring 1712 during this fabrication process.

Referring next to FIG. 17f, a mirror stack 1714 is then formed in the same way as previously described with reference to FIG. 16: In embodiments a sacrificial layer of photoresist (or amorphous carbon) is deposited and patterned, etching trenches to define posts for the mirrors. The mirror stack is then deposited by PVD, and patterned and etched to define hexagonal mirrors. The sacrificial photoresist (or amorphous carbon) is then ashed to leave the mirrors 1714 each tacked by a central post to a corresponding mirror support 1712a, part of the mirror spring 1712. This leaves the structure shown in FIG. 17f. This structure is then etched using an anhydrous vapour HF etch to remove the sacrificial oxide walls 1704, leaving the structure schematically illustrated in FIG. 17g. In practice the spring support walls 1702 are also etched a little, but as shown in FIG. 17c preferably the sacrificial walls 1704 are thinner than the spring supporting walls 1702. For example the thickness of a spring supporting wall 1702 may be of order 1.0 μm whereas the thickness of a sacrificial wall 1704 may be of order 0.25 μm.

FIGS. 17h and 17i, in which like elements to those previously described are indicated by like reference numerals, show vertical cross section and plan views respectively of a variant of the configuration of the sacrificial walls 1704, in which the walls define a set of parallel lines spaced apart across the width of a pixel cell. FIG. 17h illustrates schematically the view looking along these parallel lines showing the result of the final etch to remove these sacrificial supporting walls.

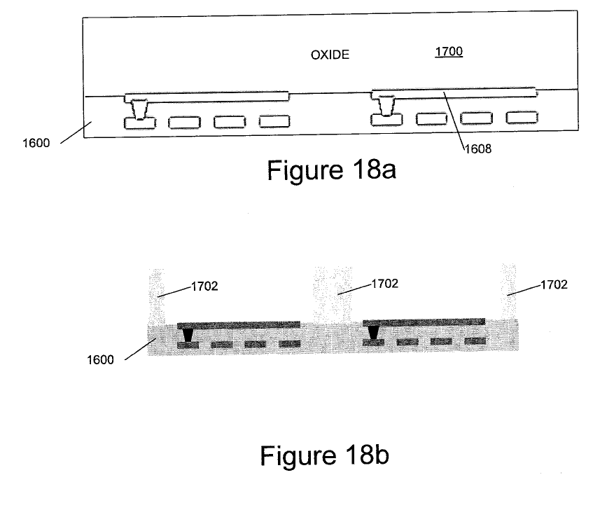

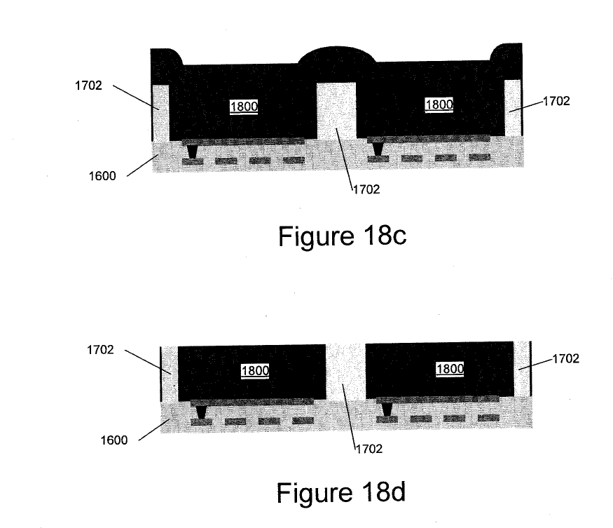

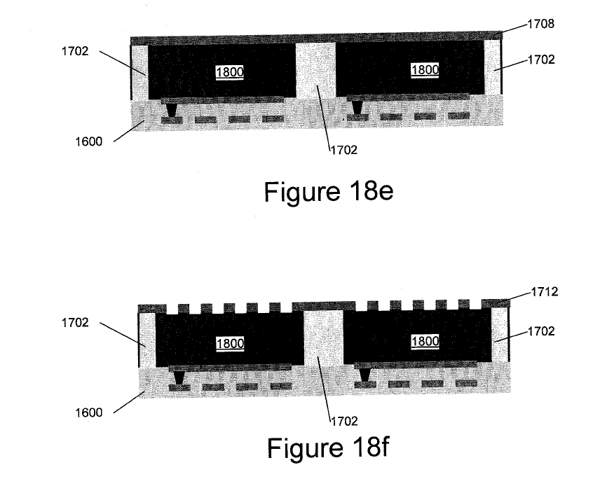

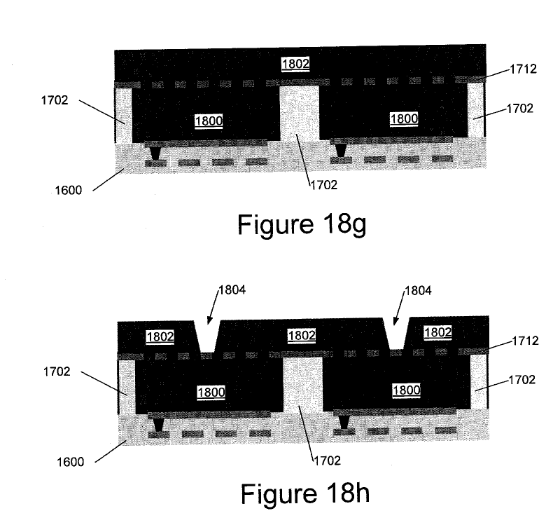

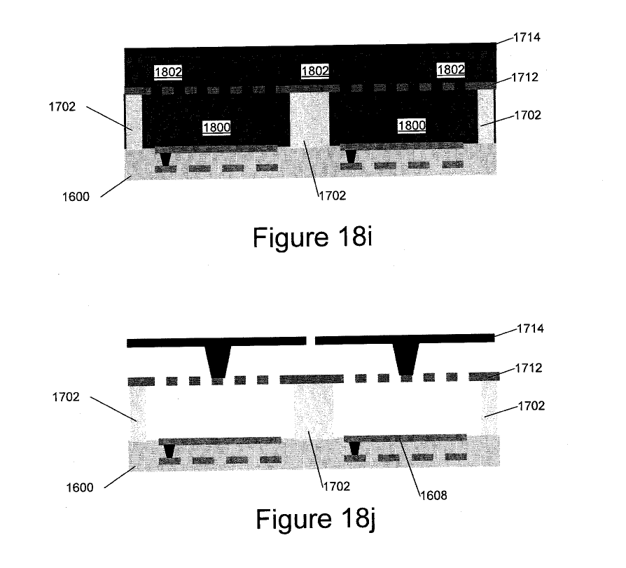

FIG. 18 shows a variant of the process of FIG. 17, in which like elements are indicated by like reference numerals. Thus FIG. 18a broadly corresponds to FIG. 17a but in FIG. 18b, rather than patterning and etching the oxide to leave sacrificial walls, only the spring support structure walls 1702 are left by comparison with FIG. 17b. Then in FIG. 18c a sacrificial layer of amorphous carbon 1800 is deposited and planarised by CMP polishing so that the top of this layer is flush with the side walls 1702 (FIG. 18d). The planarisation should be carried out carefully to avoid dishing of the upper surface of the amorphous carbon. In variance of this process other sacrificial materials such germanium or a metal may be employed.

Following this a silicon-on-insulator wafer is a wafer bonded to the upper surface of the structure of FIG. 18d and the handling wafer and buried offside removed as previously described, to leave a layer of single crystal silicon 1708 (FIG. 18e), which is then patterned and etched (FIG. 18f) as previously described with reference to FIG. 17e, to leave the mirror spring flexure 1712 supported by the amorphous carbon 1800. Once the spring flexure 1712 has been defined the photoresist and etch residue on the sacrificial layer 800 is removed and the structure cleaned, for example using a wet clean. In variance of this process instead of a wafer bonding a silicon layer to the top of the structure of FIG. 18d, a layer of spring material such as SiGe or metal alloy may be deposited on top of the structure and afterwards patterned to define the mirror spring.

A second sacrificial layer 1802, preferably of amorphous carbon is then deposited over the structure of FIG. 18f, as shown in FIG. 18g, and CMP planarised. This is then patterned and etched to form trenches 1804 as shown in FIG. 18h, each defining a mirror post or ‘stitch’.

The mirror stack is then deposited as previously described (FIG. 18i), the mirror plate is patterned and etched, and the photoresist and etch residue is then removed together with or followed by the sacrificial layers 1800, 1802 of a amorphous carbon, for example using an oxygen plasma ashing process, to leave the final structure of FIG. 18j.

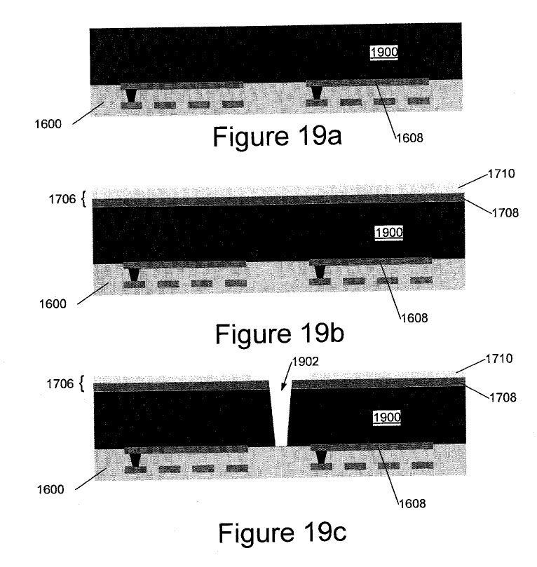

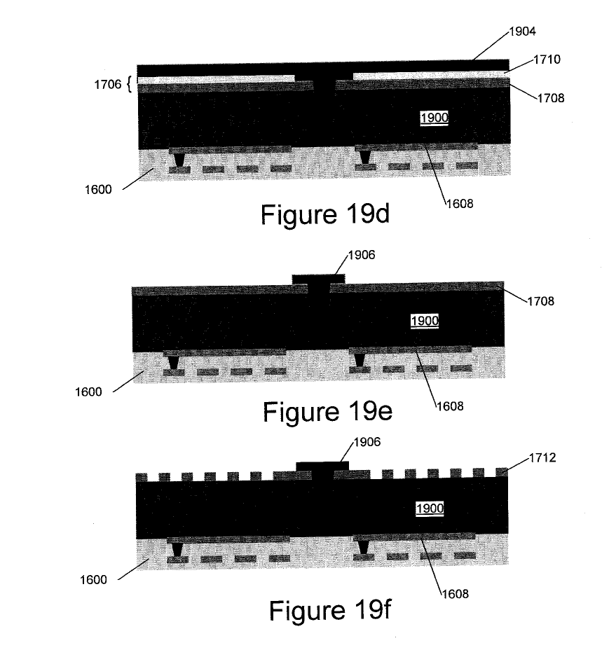

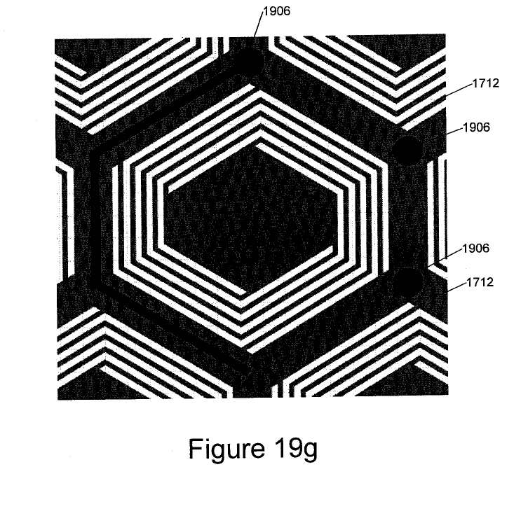

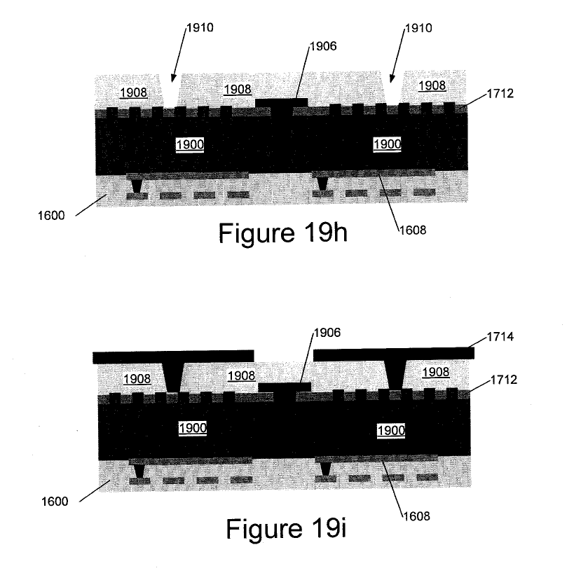

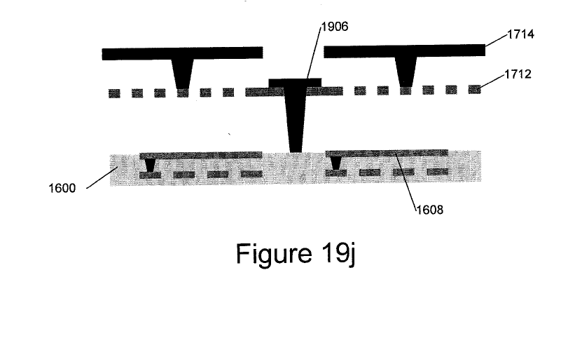

FIG. 19 shows a further variant of the fabrication process in which the mirror spring is attached to the substrate 1600 by a metal (tungsten) post, for example formed by a via process. Again like elements to those previously described are indicated by like reference numerals.

Thus in FIG. 19a a sacrificial layer 1900 of amorphous carbon is deposited over the CMOS substrate 1600 and, after CMP planarisation, a silicon-on-insulator wafer 1706 is bonded to the upper surface of this layer (FIG. 19b). The handling wafer (not shown in FIG. 19b) is removed and afterwards the oxide 1710, silicon 1708, and amorphous carbon 1900 layers are patterned and etched to define a rivet-shaped via or trench 1902. A layer of rivet material 1904 is then deposited to fill the via or trench, for example comprising metal in particular tungsten (FIG. 19d). This is then etched using the patterned oxide layer 1710 as an etch stop, and the etch stop is then removed to leave the structure shown in FIG. 19e in which the mirror spring layer 1708 is supported and attached to the CMOS substrate by (tungsten) post or ‘rivet’ 1906. The spring layer 1708 is then patterned to define the mirror spring 1712, as previously described (FIG. 19f). FIG. 19g shows a planned view of the structure of FIG. 19f, showing in embodiments, a conductive strip of tungsten metal extending at least partially around the perimeter of the mirror spring.

In this and in previous embodiments of the process the mirror spring acts as the upper electrode of the pixel structure and is thus electrically connected to an output portion of the pixel drive circuitry in the CMOS substrate. This may be achieved by a via in a supporting wall 1702 (not illustrated in FIGS. 16 to 18, for simplicity), but in the process of FIG. 19 the spring-supporting rivet 1906 may also serve as an electrical connection between the spring and the CMOS substrate 1600.

Following etching of the mirror spring, the structure is cleaned to remove post-etch residue on the amorphous carbon, for example using a wet post-etch clean. A further sacrificial layer 1908, for example of photoresist, is then deposited on the structure of FIG. 19f, and patterned to define a region 1910 for a mirror post or ‘stitch’ (FIG. 19h). The mirror spec 1714 is then deposited and patterned to leave the mirrors mounted on the mirror springs, but still supported by the sacrificial layers, as shown in FIG. 19i. All the sacrificial material is then stripped using an oxygen plasma ashing process, to leave the completed structure as shown in FIG. 19j.

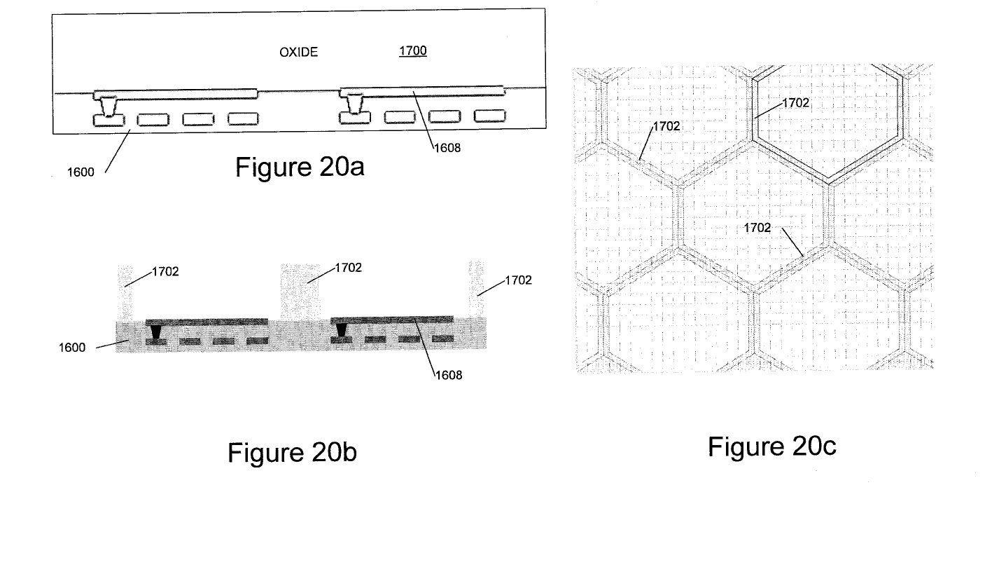

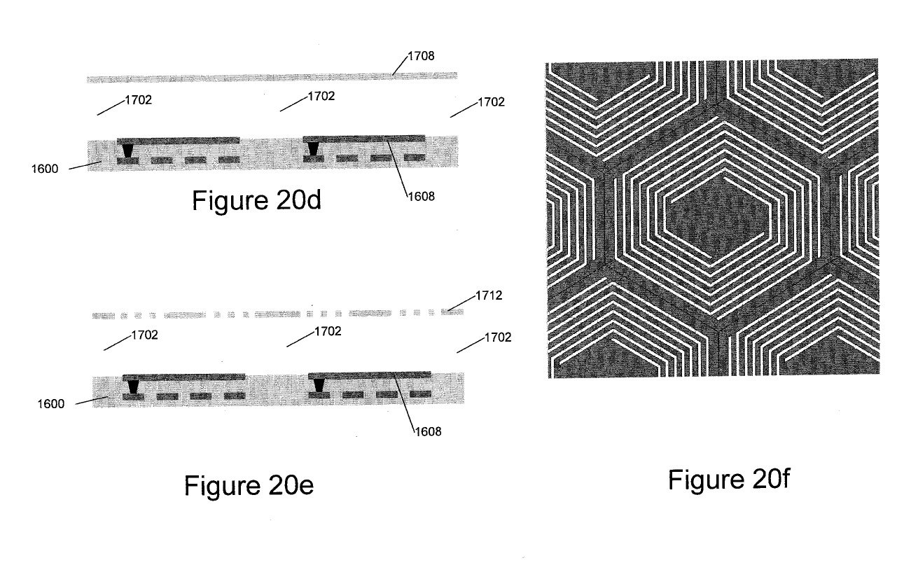

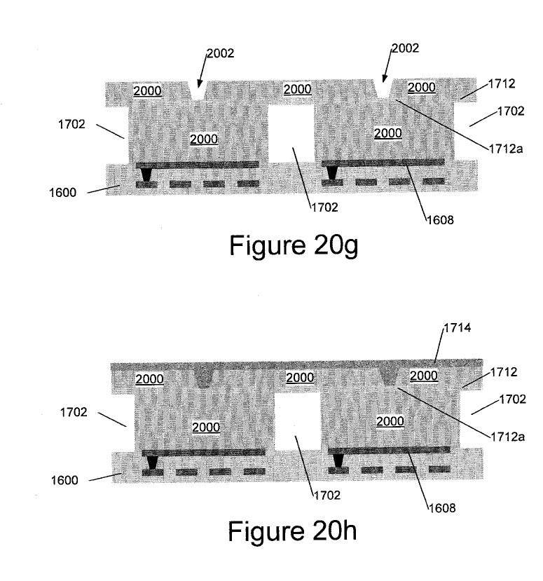

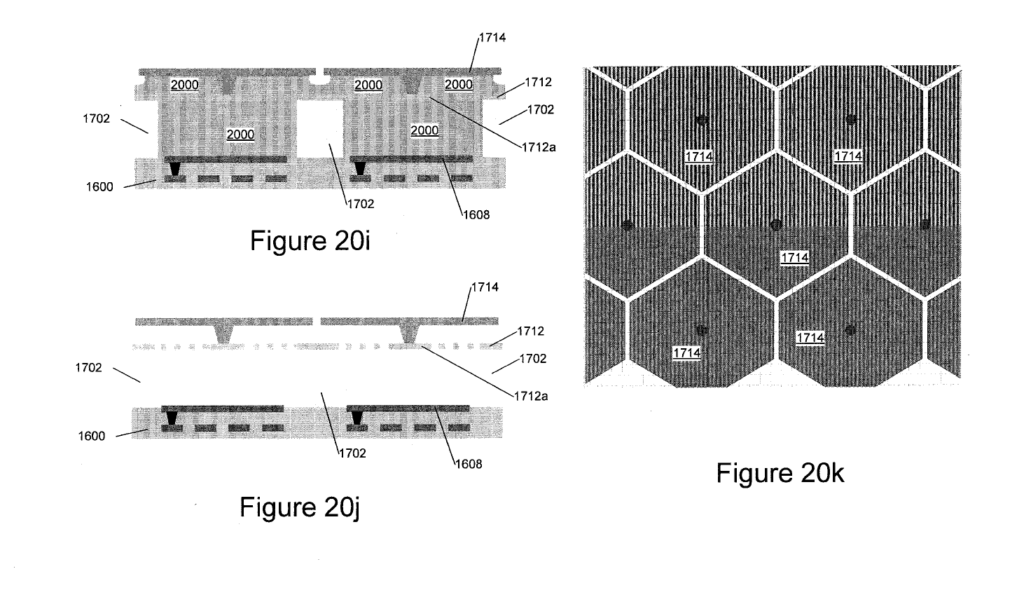

Referring now to FIG. 20, this shows a still further variant of the process in which, again, like features are indicated by like referencing rules. Thus FIG. 20a corresponds to FIG. 17a, but afterwards the oxide layer 1700 is etched to leave the spring support walls 1702, but no sacrificial oxide walls 1704. Thus a planned view of the structure of FIG. 20b is shown in FIG. 20c and can be compared with other structures of FIG. 17c in which sacrificial spring support structures are present. Then (FIGS. 20d, e) a silicon-on-insulator wafer is bonded to the side walls 1702 and patterned to leave the mirror spring 1712; a planned view of the resulting structure is shown in FIG. 20f. This approach is, however, less preferable than those previously described because at the FIG. 20e stage the spring is unsupported in its central region over the bottom pixel electrode.

Sacrificial photoresist 2000 is then deposited to fill the region between the mirror spring and the CMOS substrate, also extending above the mirror spring to provide support for the mirror stack. This layer is then patterned to define trenches or stitches 2002 down to the mirror support part 1712a of the mirror spring (FIG. 20g) and afterwards the mirror stack mirrors are deposited (FIG. 20h) and patterned (FIG. 20i) to define hexagonal mirrors. The photoresist is then removed, for example by an ashing process, to leave the final structure shown in cross-section in FIG. 20j and, schematically in plan view in FIG. 20k.

The skilled person will appreciate that further variants on the above described fabrication process are possible.

To summarise, broadly speaking in one approach amorphous carbon is deposited onto the CMOS substrate and patterned to define trenches down to the substrate, after which SiGe (or a metal alloy) is deposited to form a mirror spring (having an electrical connection to the substrate). A second sacrificial layer is then deposited over the structure and patterned to define a passage down to the mirror support, the mirror stack is then deposited, and the entire structure is afterwards ashed to remove the sacrificial material. Oxide may be substituted for amorphous carbon (or photoresist) and etched with HF.

In another approach an SoI wafer is bonded to the top of a spring support structure to provide a single crystal silicon spring, but in this case it is strongly preferable to provide one or more sacrificial structures within the cavity between the spring and the CMOS substrate and/or to fill this cavity with a sacrificial material such as amorphous carbon, to support the mirror spring during its fabrication. Thus broadly speaking in this set of processes offside is deposited over the CMOS substrate and patterned to define at least walls to support the mirror spring, and optionally additional sacrificial walls to support the spring during its fabrication and/or the MEMS pixel cell cavity is filled with sacrificial material such as amorphous carbon. The SoI wafer is then bonded, silicon face towards the CMOS substrate, to the structure and thinned/etched to leave the silicon, in which the mirror spring is formed. Then a further sacrificial layer of material, for example photoresist or amorphous carbon, is deposited and used to support the fabrication of the mirror, and then the sacrificial support structures are removed by ashing and/or etching the sacrificial spring-supporting walls, posts or other structures. In such a process a (deposited) layer of SiGe may be substituted for the silicon layer derived from the SoI wafer. In embodiments of this set of methods a conductive via or stitch is also provided in between the electrically conductive mirror spring and the CMOS substrate, more particularly the pixel driver circuitry, so that the structure may be driven by a voltage applied between the bottom pixel electrode and the mirror spring.

In a further variant the CMOS substrate is provided with a sacrificial layer, for example of amorphous carbon, which is a layer of silicon and then a layer of oxide are then provided over the (amorphous carbon) sacrificial material, either by bonding an SoI wafer to the structure or by deposition this structure is then patterned to define connections down to the CMOS substrate, optionally using the silicon and/or oxide layers as masks; alternatively the sacrificial layer may be patterned prior to providing the silicon and/or oxide layers over this. Once connections down to the CMOS substrate have been defined, an electrically conducting material such as tungsten is deposited into the connection to provide an electrical and mechanical connection between CMOS substrate and the silicon layer, and the mirror spring is then formed in this silicon layer. The skilled person will appreciate in this and the previously described processes, the order of steps within the processes may be changed.

No doubt many other effective alternatives will occur to the skilled person. It will be understood that the invention is not limited to the described embodiments and encompasses modifications apparent to those skilled in the art lying within the spirit and scope of the claims appended hereto.

What is claimed is:

1. A phase modulating spatial light modulator (SLM), the spatial light modulator comprising:
a substrate bearing a plurality of SLM pixels, each of said SLM pixels comprising a MEMS (micro electromechanical system) optical phase modulating structure;
wherein said MEMS optical phase modulating structure comprises:
a pixel electrode;
a spring support structure around a perimeter of said pixel electrode;
a mirror spring supported by said spring support structure, wherein said mirror spring comprises a mirror support and a plurality of mirror spring arms each extending between said mirror support and said spring support structure; and
a mirror mounted on said mirror support; and
wherein a voltage applied to said pixel electrode flexes said mirror spring and translates said mirror perpendicularly to said substrate substantially without tilting.

2. A phase modulating SLM as claimed in claim 1 wherein said mirror spring is electrically conductive and wherein a ratio of a distance between said mirror spring arms to a distance between said mirror spring and said pixel electrode is at least 1:2.

3. A phase modulating SLM as claimed in claim 1 wherein said optical phase modulating structure is located over CMOS pixel drive circuitry for the structure; and wherein said pixel electrode is electrically coupled to said pixel drive circuitry for a pixel.

4. A phase modulating SLM as claimed in claim 1 wherein said mirror spring is substantially planar.

5. A phase modulating SLM as claimed in claim 1 wherein said mirror support is integrally formed with said mirror spring.

6. A phase modulating SLM as claimed in claim 5 wherein said mirror support and mirror spring comprise SiGe.

7. A phase modulating SLM as claimed in claim 1 wherein each said mirror spring arm has a generally spiral shape.

8. A phase modulating SLM as claimed in claim 7 wherein each said mirror spring arm has a length of at least 0.5 turns of said spiral.

9. A phase modulating SLM as claimed in claim 7 wherein each said mirror spring arm has a length of at least 1 turn of said spiral.

10. A phase modulating SLM as claimed in claim 1 wherein each said mirror spring arm has a serpentine shape

11. A phase modulating SLM as claimed in claim 1 wherein said mirror has substantially the shape of an irregular hexagon.

12. A phase modulating spatial light modulator (SLM), the spatial light modulator comprising:
a substrate bearing a plurality of SLM pixels, each of said SLM pixels comprising a MEMS (micro electromechnical system) optical phase modulating structure over CMOS pixel drive circuitry for the structure;
wherein said MEMS optical phase modulating structure comprises:
a pixel electrode coupled to said pixel drive circuitry for a pixel;
a mirror spring moveable in a direction perpendicular to said substrate by an electric field applied by said pixel electrode; and
a mirror mounted on said mirror-spring; and
wherein a voltage is applied by said CMOS pixel drive circuitry to said pixel electrode flexes said mirror spring to translate said mirror perpendicularly to said substrate substantially without tilting.

13. A phase modulating spatial light modulator SLM as claimed in claim 12 wherein said mirror spring is electrically conductive and electrically coupled to said CMOS pixel drive circuitry.

14. A phase modulating spatial light modulator (SLM) as claimed in claim 13 wherein said CMOS pixel drive circuitry is configured to apply a variable analogue drive voltage between said mirror spring and said pixel electrode to translate said mirror to a variable analogue position above said substrate.

15. A method of fabricating an optical phase modulating MEMS spatial light modulator, the method comprising:
providing a substrate;
depositing a sacrificial spring support structure on said substrate;
providing a layer of spring material over said sacrificial spring support structure;
patterning said layer of spring material to define a mirror spring supported by said spring support structure, wherein said mirror spring comprises a mirror support and a plurality of mirror spring arms each extending between said mirror support and said spring support structure, wherein each said mirror spring arm has a spiral or serpentine shape;
forming a mirror mounted on said mirror support; and
removing said sacrificial spring support structure.

16. A method as claimed in claim 15 wherein said sacrificial spring support structure comprises amorphous carbon.

17. A method as claimed in claim 15 wherein said sacrificial spring support structure comprises one or more walls or pillars.

18. A method as claimed in claim 15 wherein said sacrificial spring support structure comprises oxide, and wherein the method further comprises using a hydrofluoric acid etch to remove said oxide sacrificial spring layer after forming said mirror.

19. A method of fabricating a MEMS device, the method comprising:
providing a CMOS substrate;
depositing at least one layer of amorphous carbon as a sacrificial layer;
providing at least one layer of said MEMS device over said amorphous carbon layer;
removing said sacrificial layer of amorphous carbon to fabricate said MEMS device.

20. A method as claimed in claim 19 further comprising depositing a barrier layer between said at least one layer of amorphous carbon and said at least one layer of said MEMS device.

21. A method as claimed in claim 20 wherein said barrier layer comprises amorphous silicon, and said at least one layer of said MEMS device comprises SiGe.

22. A method as claimed in claim 19 further comprising patterning said at least one layer of amorphous carbon prior to providing said at least one layer of said MEMS device over said amorphous carbon layer.

23. A method as claimed in claim 19 further comprising one or both of planarising and polishing said layer of amorphous carbon prior to providing said at least one layer of said MEMS device over said amorphous carbon layer.

24. A method as claimed in claim 19 wherein said providing of said at least one layer of said MEMS device comprises depositing said at least one layer of said MEMS device.

25. A method as claimed in of claim 19 bonding a silicon layer over said amorphous carbon layer.

26. A method as claimed in claim 25 wherein said silicon layer comprises a layer of a silicon-on-insulator structure.

27. A method as claimed in claim 19 further comprising exposing a top metal layer of said CMOS substrate prior to depositing said at least one layer of amorphous carbon.

28. A method as claimed in claim 19 further comprising depositing a second layer of amorphous carbon over said at least one layer of said MEMS device as a second sacrificial layer.

29. A method as claimed in claim 19 wherein said at least one layer of said MEMS device comprises a mechanical spring layer, the method further comprising patterning a spiral or serpentine mechanical spring in said spring layer whilst said mechanical spring layer is supported by said amorphous carbon layer.

30. A method as claimed in claim 29 further comprising fabricating a mirror on said mechanical spring layer, supported by and vertically spaced away from said mechanical spring.

31. A method as claimed in claim 30 further comprising supporting said mirror during fabrication by a further said sacrificial layer of amorphous carbon.

32. A method as claimed in claim 19 further comprising packaging said MEMS device for use.
